(19) United States
(12) Patent Application Publication
(10) Pub. No.: US 2023/0066186 A1
(43) Pub. Date: Mar. 2, 2023

(54) SEMICONDUCTOR DEVICES, METHODS OF MANUFACTURING THE SAME, AND ELECTRONIC SYSTEMS INCLUDING THE SEMICONDUCTOR DEVICES

(71) Applicant: Samsung Electronics Co., Ltd., Suwon-si (KR)

(72) Inventors: Sangmin Kang, Hwaseong-si (KR); Hyungjoon Kim, Yongin-si (KR); Sangsoo Lee, Seongnam-si (KR); Woojin Jang, Suwon-si (KR); Dongsung Choi, Hwaseong-si (KR)

(21) Appl. No.: 17/893,274

(22) Filed: Aug. 23, 2022

(30) Foreign Application Priority Data
Sep. 1, 2021 (KR) 10-2021-0116507

(51) Int. Cl. H01L 27/11582; G11C 16/04; H01L 27/11519; H01L 27/11524; H01L 27/11526; H01L 27/11556; H01L 27/11565; H01L 27/1157; H01L 27/11573

(52) U.S. Cl. CPC H01L 27/11582; G11C 16/0483; H01L 27/11519; H01L 27/11524; H01L 27/11526; H01L 27/11556; H01L 27/11565; H01L 27/1157; H01L 27/11573

(57) ABSTRACT

A semiconductor device and a method of manufacturing the same. The method may include: forming a mold stack that includes a plurality of insulating layers alternately arranged with a plurality of sacrificial layers; forming a preliminary pad portion by sequentially patterning the mold stack; forming a cell contact hole that extends through the preliminary pad portion and the sacrificial layer portions; forming a first extension portion and a plurality of second extension portions by laterally expanding the preliminary pad portion and the sacrificial layer portions; forming a first insulating liner and a sacrificial ring pattern in the first extension portion; forming an oxide liner and an insulating ring pattern in the second extension portions; forming a sacrificial plug within the cell contact hole; and replacing the sacrificial layers with gate electrodes and replacing the preliminary pad portion, the first insulating liner, and the sacrificial ring pattern with a pad portion.

### CROSS-REFERENCE TO RELATED APPLICATION

This application is based on and claims priority under 35 U.S.C. § 119 to Korean Patent Application No. 10-2021-0116507, filed on Sep. 1, 2021, in the Korean Intellectual Property Office, the disclosure of which is incorporated by reference herein in its entirety.

### TECHNICAL FIELD

The present disclosure relates to semiconductor devices, methods of manufacturing the semiconductor devices, and electronic systems including the semiconductor devices. More particularly, the present disclosure relates to semiconductor devices having a vertical channel, method of manufacturing the semiconductor devices, and electronic systems including the semiconductor devices.

### BACKGROUND

Semiconductor devices capable of storing high-capacity data have been increasingly deployed in electronic systems that require data storage. Accordingly, methods for increasing the data storage capacity of semiconductor devices have been researched and proposed. For example, one proposed method for increasing the data storage capacity of semiconductor devices considers semiconductor devices that include three-dimensionally arranged memory cells instead of two-dimensionally arranged memory cells.

### SUMMARY

The present disclosure provides a semiconductor device that is capable of preventing or reducing a rate of occurrence of a failure in a pad structure forming process and methods of manufacturing the semiconductor device.

The present disclosure also provides an electronic system including the semiconductor device.

According to some aspects of the inventive concepts, there is provided a method of manufacturing a semiconductor device, and the method may include: forming a mold stack including a plurality of insulating layers alternately arranged with a plurality of sacrificial layers on a substrate; forming a preliminary pad structure by sequentially patterning the mold stack, wherein the preliminary pad structure includes a preliminary pad portion connected to at least one sacrificial layer among the plurality of sacrificial layers and the preliminary pad portion has a greater thickness than the at least one sacrificial layer in a vertical direction that is perpendicular to an upper surface of the substrate; forming a cell contact hole that extends in the vertical direction through the preliminary pad portion and a plurality of sacrificial layer portions under the preliminary pad portion; forming a first extension portion and a plurality of second extension portions by laterally expanding the preliminary pad portion and the plurality of sacrificial layer portions exposed at an inner wall of the cell contact hole; forming a first insulating liner and a sacrificial ring pattern in the first extension portion; forming an oxide liner and an insulating ring pattern in each of the plurality of second extension portions; forming a sacrificial plug within the cell contact hole; and replacing the plurality of sacrificial layers with a plurality of gate electrodes and replacing the preliminary pad portion, the first insulating liner, and the sacrificial ring pattern with a pad portion.

According to some aspects of the inventive concepts, there is provided a method of manufacturing a semiconductor device, and the method may include: forming a mold stack that includes a plurality of insulating layers and a plurality of sacrificial layers alternately arranged on a substrate; forming a preliminary pad structure by sequentially patterning the mold stack, wherein the preliminary pad structure has a stepped shape and includes a preliminary pad portion connected to at least one sacrificial layer among the plurality of sacrificial layers and the preliminary pad portion has a greater thickness than the at least one sacrificial layer in a vertical direction that is perpendicular to an upper surface of the substrate; forming a cell contact hole that extends in the vertical direction through the preliminary pad portion and a plurality of sacrificial layer portions under the preliminary pad portion and including a first extension portion extending in a horizontal direction; forming a sacrificial ring pattern in the first extension portion; forming a sacrificial plug within the cell contact hole; forming a plurality of gate spaces by removing the plurality of sacrificial layers and forming a pad space by removing the preliminary pad portion and the sacrificial ring pattern; forming a dielectric liner on an inner wall of the plurality of gate spaces and the pad space; forming a plurality of gate electrodes within the plurality of gate spaces on the dielectric liner and forming a pad portion within the pad space; removing the sacrificial plug to expose a sidewall of the pad portion and removing a portion of the dielectric liner exposed in the cell contact hole; and forming, in the cell contact hole, a cell contact plug contacting the sidewall of the pad portion and extending in the vertical direction.

According to some aspects of the inventive concepts, there is provided a method of manufacturing a semiconductor device, and the method may include: forming a mold stack that includes a plurality of insulating layers and a plurality of sacrificial layers alternately arranged on a substrate; forming a preliminary pad structure by sequentially patterning the mold stack, wherein the preliminary pad structure includes a preliminary pad portion connected to at least one sacrificial layer among the plurality of sacrificial layers; forming a cell contact hole extending in a vertical direction through the preliminary pad portion and a plurality of sacrificial layer portions under the preliminary pad portion; forming a first extension portion and a plurality of second extension portions by laterally expanding the preliminary pad portion and the plurality of sacrificial layer portions exposed at an inner wall of the cell contact hole; forming an insulating liner on an inner wall of the cell contact hole, an inner wall of the first extension portion, and an inner wall of the plurality of second extension portions; forming a sacrificial ring pattern within the first extension portion on the inner wall of the first extension portion; converting a portion of the insulating liner arranged on the inner wall of the plurality of second extension portions into an oxide liner by performing an oxidation process; forming a plurality of insulating ring patterns respectively within the plurality of second extension portions on the inner wall of the plurality of second extension portions; forming a sacrificial plug within the cell contact hole; and replacing the plurality of sacrificial layers with a plurality of gate electrodes and replacing the preliminary pad portion, the insulating liner, and the sacrificial ring pattern with a pad portion.

### BRIEF DESCRIPTION OF THE DRAWINGS

Aspects of the present disclosure and examples of embodiments thereof will be more clearly understood from the following detailed description taken in conjunction with the accompanying drawings in which:

FIG. 1 is a block diagram of a semiconductor device according to some embodiments;

FIG. 2 is an equivalent circuit diagram of a memory cell array of a semiconductor device according to some embodiments;

FIG. 3 is a perspective view illustrating a representative configuration of a semiconductor device according to some embodiments;

FIG. 4 is a plan view illustrating the semiconductor device of FIG. 3;

FIG. 5 is a cross-sectional view taken along line A-A′ of FIG. 4;

FIG. 6 is an enlarged view of region CX1 of FIG. 5;

FIG. 7 is an enlarged view of region CX2 of FIG. 5;

FIG. 8 is a cross-sectional view illustrating a semiconductor device according to some embodiments;

FIG. 9 is a cross-sectional view illustrating a semiconductor device according to some embodiments;

FIG. 10 is a cross-sectional view illustrating a semiconductor device according to some embodiments;

FIG. 11 is an enlarged view of region CX3 of FIG. 10;

FIG. 12 is a cross-sectional view illustrating a semiconductor device according to some embodiments;

FIGS. 13 to 29 are cross-sectional views illustrating a method of manufacturing a semiconductor device according to some embodiments, with FIGS. 13 to 17, 24, and 27A being cross-sectional views corresponding to a cross-section taken along line A-A′ of FIG. 4, and FIGS. 18 to 23, 25, 26, 27B, 28, and 29 being cross-sectional views corresponding to a cross-section of region CX1 of FIG. 5;

FIG. 30 is a diagram schematically illustrating a data storage system including a semiconductor device according to some embodiments;

FIG. 31 is a perspective view schematically illustrating a data storage system including a semiconductor device according to some embodiments; and

FIG. 32 is a cross-sectional view schematically illustrating semiconductor packages according to some embodiments.

### DETAILED DESCRIPTION OF THE EMBODIMENTS

Hereinafter, some embodiments of various aspects of the present disclosure and the inventive concepts thereof will be described in detail with reference to the accompanying drawings.

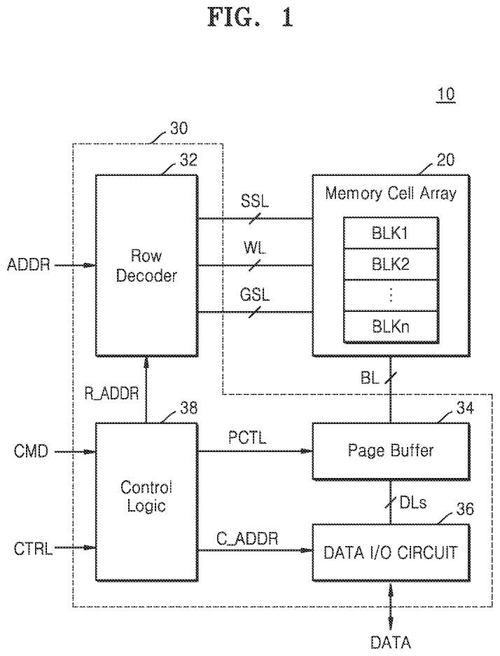

FIG. 1 is a block diagram of a semiconductor device 10 according to some embodiments.

Referring to FIG. 1, the semiconductor device 10 may include a memory cell array 20 and a peripheral circuit 30. The memory cell array 20 may include a plurality of memory cell blocks BLK1, BLK2, . . . , BLKn. Each of the plurality of memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and a control logic 38. Although not illustrated in FIG. 1, the peripheral circuit 30 may further include one or more of various components, such as an input/output interface, a column logic, a voltage generator, a predecoder, a temperature sensor, a command decoder, an address decoder, an amplifier circuit, and/or the like.

The memory cell array 20 may be connected to the page buffer 34 through the bit line BL and may be connected to the row decoder 32 through the word line WL, the string selection line SSL, and the ground selection line GSL. In the memory cell array 20, each of the plurality of memory cells included in the plurality of memory cell blocks BLK1, BLK2, . . . , BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from a first external device outside of the semiconductor device 10 and transmit/receive data DATA to/from a second external device outside the semiconductor device 10. The first and second external devices may be the same device in some embodiments.

The row decoder 32 may select at least one of the plurality of memory cell blocks BLK1, BLK2, . . . , BLKn in response to the address ADDR received from the first external device and select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver in a program operation and may apply a voltage according to data DATA to be stored in the memory cell array 20 to the bit line BL, and/or the page buffer 34 may operate as a sense amplifier in a read operation and may sense data DATA stored in the memory cell array 20. The page buffer 34 may operate according to a control signal PCTL received from the control logic 38.

The data input/output circuit 36 may be connected to the page buffer 34 through data lines DLs. In the program operation, the data input/output circuit 36 may receive data DATA from a memory controller (not illustrated) and provide program data DATA to the page buffer 34 based on a column address C_ADDR received from the control logic 38. In the read operation, the data input/output circuit 36 may provide the read data DATA stored in the page buffer 34 to the memory controller based on the column address C_ADDR received from the control logic 38.

The data input/output circuit 36 may transmit an input address or command to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide a column address C_ADDR to the data input/output circuit 36. The control logic 38 may generate various internal control signals used in the semiconductor device 10 in response to the control signal CTRL. For example, the control logic 38 may adjust a voltage level provided to the word line WL and the bit line BL in a memory operation such as the program operation or an erase operation.

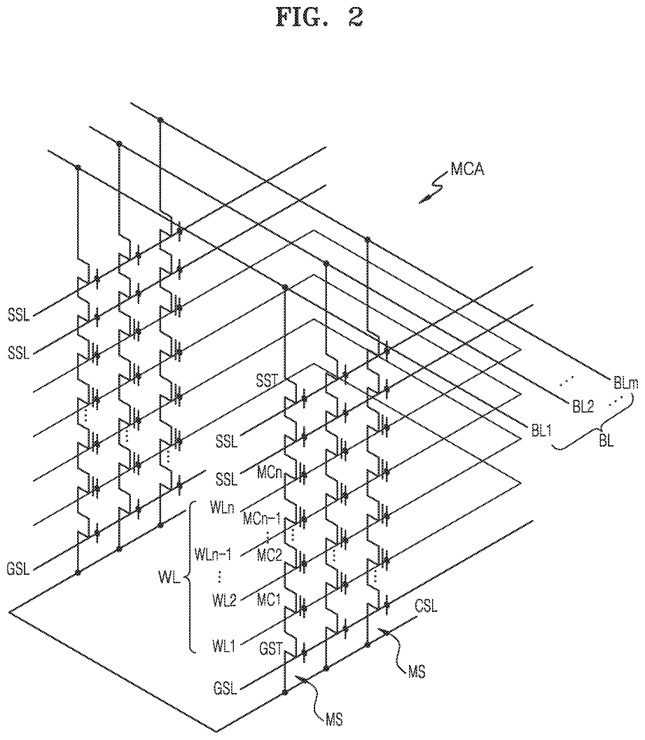

FIG. 2 is an equivalent circuit diagram of a memory cell array of a semiconductor device 10 according to some embodiments.

Referring to FIG. 2, a memory cell array MCA may include a plurality of memory cell strings MS. The memory cell array MCA may include a plurality of bit lines BL (BL1, BL2, . . . , BLm), a plurality of word lines WL (WL1, WL2, . . . , WLn−1, WLn), at least one string selection line SSL, at least one ground selection line GSL, and a common source line CSL. The plurality of memory cell strings MS may be formed between the plurality of bit lines BL (BL1, BL2, . . . , BLm) and the common source line CSL. Although FIG. 2 illustrates a case where each of the plurality of memory cell strings MS includes two string selection lines SSL, the present disclosure and the inventive concepts thereof are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn−1, MCn. A drain area of the string selection transistor SST may be connected to the bit lines BL (BL1, BL2, . . . , BLm), and a source area of the ground selection transistor GST may be connected to the common source line CSL. The common source line CSL may be an area where the source areas of a plurality of ground selection transistors GST are connected in common.

The string selection transistor SST may be connected to the string selection line SSL, and the ground selection transistor GST may be connected to the ground selection line GSL. The plurality of memory cell transistors MC1, MC2, . . . , MCn−1, and MCn may be respectively connected to the plurality of word lines WL (WL1, WL2, . . . , WLn−1, WLn).

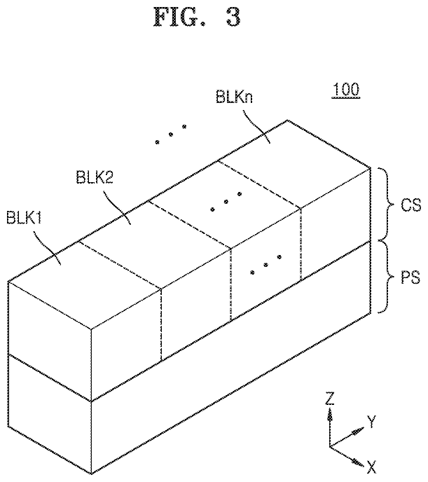

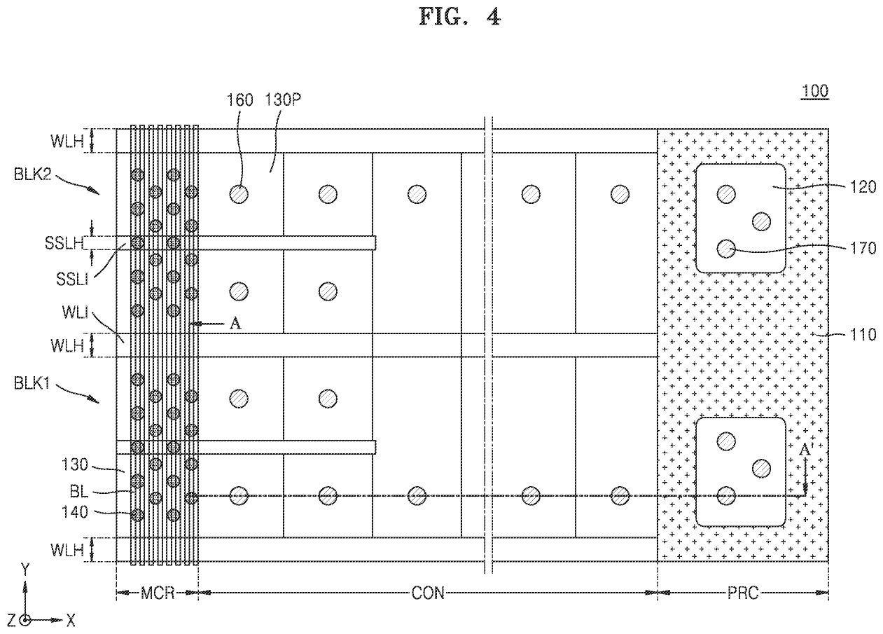

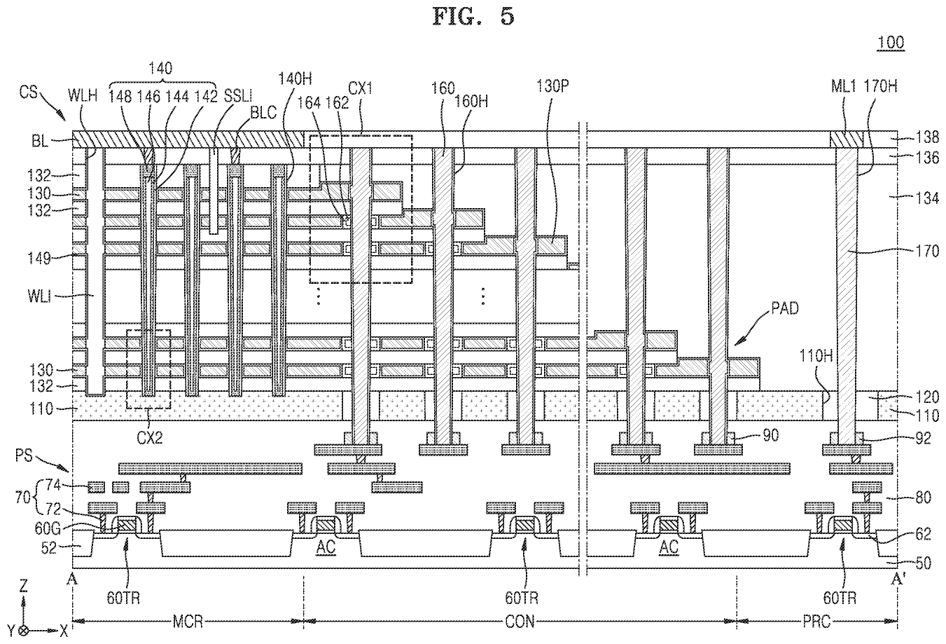

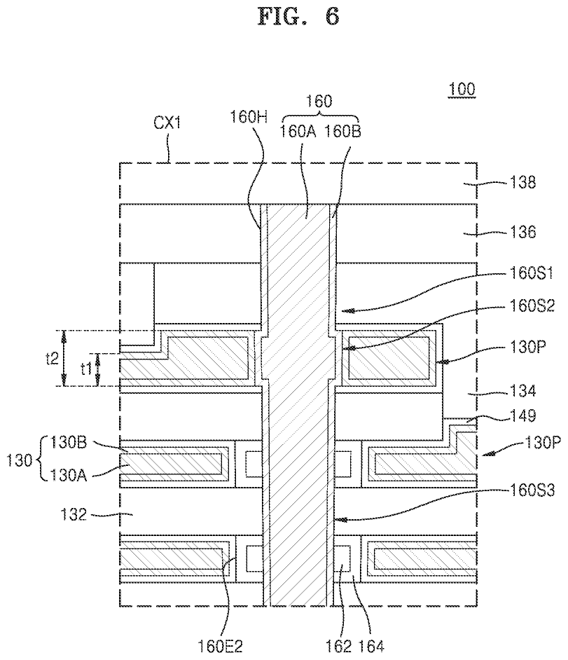

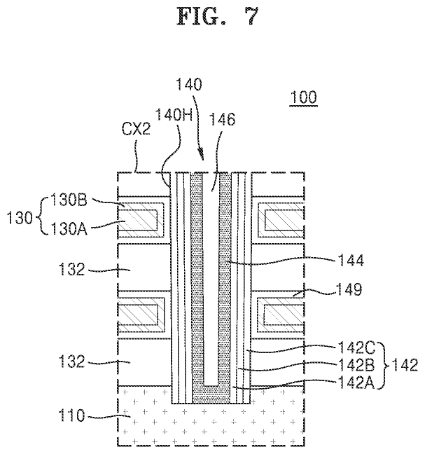

FIGS. 3 to 7 are diagrams for describing a semiconductor device 100 according to some embodiments. Particularly, FIG. 3 is a perspective view illustrating a representative configuration of a semiconductor device 100 according to some embodiments, and FIG. 4 is a plan view illustrating the semiconductor device 100 of FIG. 3. FIG. 5 is a cross-sectional view taken along line A-A′ of FIG. 4. FIG. 6 is an enlarged view of region CX1 of FIG. 5, and FIG. 7 is an enlarged view of region CX2 of FIG. 5.

Referring to FIGS. 3 to 7, the semiconductor device 100 may include a cell array structure CS and a peripheral circuit structure PS overlapping each other in a vertical direction Z. The cell array structure CS may include the memory cell array 20 described with reference to FIG. 1, and the peripheral circuit structure PS may include the peripheral circuit 30 described with reference to FIG. 1.

The cell array structure CS may include a plurality of memory cell blocks BLK1, BLK2, . . . , BLKn. Each of the plurality of memory cell blocks BLK1, BLK2, . . . , BLKn may include three-dimensionally arranged memory cells.

The peripheral circuit structure PS may include a peripheral circuit transistor 60TR and a peripheral circuit line structure 70 arranged on a substrate 50. The substrate 50 may include a memory cell area MCR, a connection area CON, and a peripheral circuit connection area PRC that are horizontally arranged (e.g., arranged side-by-side in a first horizontal direction X). In the substrate 50, an active area AC may be defined by a device isolation layer 52, and a plurality of peripheral circuit transistors 60TR may be formed on the active area AC. The plurality of peripheral circuit transistors 60TR may include a peripheral circuit gate 60G and a source/drain area 62 arranged in a portion of the substrate 50 on first and second sides of the peripheral circuit gate 60G.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or as an epitaxial layer. In some embodiments, the substrate 50 may include a silicon-on-insulator (SOI) substrate or a germanium-on-insulator (GeOI) substrate.

The peripheral circuit line structure 70 may include a plurality of peripheral circuit contacts 72 and a plurality of peripheral circuit line layers 74. An interlayer insulating layer 80 that covers the peripheral circuit transistor 60TR and the peripheral circuit line structure 70 may be arranged on the substrate 50. The plurality of peripheral circuit line layers 74 may have a multilayer structure including a plurality of metal layers arranged at different vertical levels.

A common source plate 110 may be arranged on the interlayer insulating layer 80. In some embodiments, the common source plate 110 may function as a source area that supplies a current to vertical memory cells formed in the cell array structure CS. The common source plate 110 may be arranged on the memory cell area MCR, the connection area CON, and the peripheral circuit connection area PRC of the substrate 50.

In some embodiments, the common source plate 110 may include silicon (Si), germanium (Ge), silicon germanium (SiGe), gallium arsenide (GaAs), indium gallium arsenide (InGaAs), aluminum gallium arsenide (AlGaAs), or any combination thereof. Also, the common source plate 110 may include a semiconductor doped with an n-type dopant. Also, the common source plate 110 may have a crystalline structure including at least one of a monocrystalline structure, an amorphous structure, and a polycrystalline structure. In some embodiment, the common source plate 110 may include polysilicon doped with an n-type dopant.

The common source plate 110 may include an opening portion 110H arranged on the connection area CON and the peripheral circuit connection area PRC of the substrate 50, and an insulating plug 120 may fill or be within the opening portion 110H of the common source plate 110. The insulating plug 120 may have a top surface arranged at the same level as the top surface of the common source plate 110.

A plurality of gate electrodes 130 and a plurality of mold insulating layers 132 may be alternately arranged in a vertical direction Z on the common source plate 110 on the memory cell area MCR and the connection area CON. The vertical direction Z may be perpendicular to the upper surface of the substrate 50.

As illustrated in FIG. 7, the gate electrode 130 may include a buried conductive layer 130A and a conductive barrier layer 130B surrounding the top surface, bottom surface, and at least one side surface of the buried conductive layer 130A. For example, the buried conductive layer 130A may include a metal such as tungsten, nickel, or cobalt, tantalum, a metal silicide such as tungsten silicide, nickel silicide, cobalt silicide, or tantalum silicide, doped polysilicon, or any combination thereof. In some embodiments, the conductive barrier layer 130B may include titanium nitride, tantalum nitride, tungsten nitride, or any combination thereof.

In some embodiments, the plurality of gate electrodes 130 may correspond to a ground selection line GSL, a word line WL (WL1, WL2, . . . , WLn−1, WLn), and at least one string selection line SSL constituting a memory cell string MS (see FIG. 2). For example, the lowermost gate electrode 130 may function as a ground selection line GSL, the two uppermost gate electrodes 130 may function as a string selection line SSL, and the other gate electrodes 130 may function as a word line WL. Accordingly, a memory cell string MS in which a ground selection transistor GST, a string selection transistor SST, and a memory cell transistor (MC1, MC2, . . . , MCn−1, MCn) therebetween are connected in series may be provided. In some embodiments, at least one of the gate electrodes 130 may function as a dummy word line; however, the inventive concepts of the present disclosure are not limited thereto.

As illustrated in FIG. 4, a plurality of gate stack separation opening portions WLH may extend on the common source plate 110 in a first horizontal direction X parallel to the top surface of the common source plate 110. A plurality of gate electrodes 130 arranged between a pair of gate stack separation opening portions WLH may constitute one block. For example, a first block BLK1 and a second block BLK2 are illustrated in FIG. 4.

A gate stack separation insulating layer WLI may filling the gate stack separation opening portion WLH be arranged on the common source plate 110. The gate stack separation insulating layer WLI may include silicon oxide, silicon nitride, SiON, SiOCN, SiCN, or any combination thereof.

A plurality of channel structures 140 may extend on the memory cell area MCR in the vertical direction (the Z direction) from the top surface of the common source plate 110 through the plurality of gate electrodes 130 and the plurality of mold insulating layers 132. The plurality of channel structures 140 may be arranged apart from each other at certain intervals in the first horizontal direction X, a second horizontal direction Y, and a third horizontal direction (e.g., a diagonal direction). The plurality of channel structures 140 may be arranged in a zigzag shape or a staggered shape.

Each of the plurality of channel structures 140 may be arranged in a channel hole 140H on the memory cell area MCR. Each of the plurality of channel structures 140 may include a gate insulating layer 142, a channel layer 144, a buried insulating layer 146, and a conductive plug 148. The gate insulating layer 142 and the channel layer 144 may be sequentially arranged on the sidewall of the channel hole 140H. For example, the gate insulating layer 142 may be arranged on and conform to the sidewall of the channel hole 140H, and the channel layer 144 may be arranged on and conform to the sidewall and bottom portion of the channel hole 140H. The buried insulating layer 146 may fill the remaining space of the channel hole 140H may be arranged on the channel layer 144. The conductive plug 148 may contact the channel layer 144 and may block the inlet of the channel hole 140H and may be arranged on the top side of the channel hole 140H. In some embodiments, the buried insulating layer 146 may be omitted, and the channel layer 144 may be formed in a pillar shape to fill a portion of the channel hole 140H.

In some embodiments, the channel layer 144 may be arranged to contact the top surface of the common source plate 110 at the bottom portion of the channel hole 140H. In some examples, as illustrated in FIG. 5, the bottom surface of the channel layer 144 may be arranged at a lower vertical level than the top surface of the common source plate 110; however, the inventive concepts and the present disclosure are not limited thereto.

As illustrated in FIG. 7, the gate insulating layer 142 may have a structure that sequentially includes a tunneling dielectric layer 142A, a charge storage layer 142B, and a blocking dielectric layer 142C on the outer wall of the channel layer 144. The relative thicknesses of the tunneling dielectric layer 142A, the charge storage layer 142B, and the blocking dielectric layer 142C constituting the gate insulating layer 142 are not limited to those illustrated in FIG. 7 and may be variously modified.

The tunneling dielectric layer 142A may include silicon oxide, hafnium oxide, aluminum oxide, zirconium oxide, tantalum oxide, and/or the like. The charge storage layer 142B may be an area in which electrons having passed through the tunneling dielectric layer 142A from the channel layer 144 may be stored, and may include silicon nitride, boron nitride, silicon boron nitride, or doped polysilicon. The blocking dielectric layer 142C may include silicon oxide, silicon nitride, or a metal oxide having a higher dielectric constant than silicon oxide. The metal oxide may include hafnium oxide, aluminum oxide, zirconium oxide, tantalum oxide, or any combination thereof.

In some embodiments, a dielectric liner 149 may be arranged between the channel structure 140 and the gate electrode 130. For example, the dielectric liner 149 may be arranged between the channel structure 140 and the gate electrode 130 and on the top surface and bottom surface of the gate electrode 130. For example, as illustrated in FIG. 7, the dielectric liner 149 may be arranged between the conductive barrier layer 130B and the gate insulating layer 142 and between the conductive barrier layer 130B and the mold insulating layer 132. In some embodiments, the dielectric liner 149 may include silicon oxide, silicon nitride, or a metal oxide having a higher dielectric constant than silicon oxide. The metal oxide may include hafnium oxide, aluminum oxide, zirconium oxide, tantalum oxide, or any combination thereof.

In one block BLK1 or BLK2, the uppermost two gate electrodes 130 may be planarly separated into two portions by a string separation opening portion SSLH. A string separation insulating layer SSLI may be arranged in the string separation opening portion SSLH, and the two portions may be arranged apart from each other in the second horizontal direction Y with the string separation insulating layer SSLI therebetween. The two portions may constitute the string selection line SSL described with reference to FIG. 2.

The plurality of gate electrodes 130 may constitute a pad structure PAD on the connection area CON. In the connection area CON, the plurality of gate electrodes 130 may extend to have a smaller length in the first horizontal direction X as a distance increases from the top surface of the common source plate 110. In other words, a first gate electrode 130 may have a first length in the first horizontal direction X and a second gate electrode 130 may have a second length in the first horizontal direction X that is less than the first length. The second gate electrode 130 may be farther in the vertical direction Z from the top surface of the common source plate 110 than the first gate electrode 130 is from the top surface of the common source plate 110. The pad structure PAD may refer to portions of the gate electrode 130 arranged in a stepped shape. The pad structure PAD may include a plurality of pad portions 130P respectively extending from the plurality of gate electrodes 130 and having a greater thickness than the plurality of gate electrodes 130 (e.g., in the vertical direction Z).

A cover insulating layer 134 may be arranged on the pad structure PAD, and a first upper insulating layer 136 may be arranged on the uppermost mold insulating layer 132 and the cover insulating layer 134. In some embodiments, the dielectric liner 149 may extend from the top surface and bottom surface of the plurality of gate electrodes 130 to cover the top surface and bottom surface of the pad portion 130P.

A cell contact plug 160 may be arranged over the connection area CON and may pass through the first upper insulating layer 136, the cover insulating layer 134, the plurality of gate electrodes 130, and the plurality of mold insulating layers 132. The cell contact plug 160 may be arranged in a cell contact hole 160H that passes through the first upper insulating layer 136, the cover insulating layer 134, the plurality of gate electrodes 130, the plurality of mold insulating layers 132, and the insulating plug 120.

The cell contact plug 160 may include a buried conductive layer 160A that passes through the plurality of gate electrodes 130 and extending in the vertical direction Z and a conductive barrier layer 160B that surrounds the side surface and bottom surface of the buried conductive layer 160A. The buried conductive layer 160A may include, for example, a metal such as tungsten, nickel, or cobalt, tantalum, a metal silicide such as tungsten silicide, nickel silicide, cobalt silicide, or tantalum silicide, doped polysilicon, or any combination thereof. In some embodiments, the conductive barrier layer 160B may include titanium nitride, tantalum nitride, tungsten nitride, or any combination thereof.

The cell contact plug 160 may be electrically connected to the pad portion 130P corresponding thereto and may be arranged apart from at least one gate electrode 130 among the plurality of gate electrodes 130 arranged at a lower vertical level than the pad portion 130P.

For example, as illustrated in FIG. 6, the cell contact plug 160 may include an upper sidewall portion 160S1, a connection sidewall portion 160S2, and a lower sidewall portion 160S3, and the connection sidewall portion 160S2 may contact one pad portion 130P corresponding to the cell contact plug 160. The upper sidewall portion 160S1 may be arranged at a higher vertical level than the connection sidewall portion 160S2 and may be surrounded by the cover insulating layer 134 and the first upper insulating layer 136. The lower sidewall portion 160S3 may be arranged at a lower vertical level than the connection sidewall portion 160S2.

The lower sidewall portion 160S3 of the cell contact plug 160 may be surrounded by at least one mold insulating layer 132 and at least one insulating ring pattern 162. A plurality of insulating ring patterns 162 and an oxide liner 164 may be arranged between the lower sidewall portion 160S3 of the cell contact plug 160 and the plurality of gate electrodes 130. In some embodiments, the oxide liner 164 may be arranged on and conform to the inner wall of a second extension portion 160E2 of the cell contact hole 160H, and each insulating ring pattern 162 may be arranged over the oxide liner 164 to fill the second extension portion 160E2.

In some embodiments, each of the plurality of insulating ring patterns 162 may have a ring shape or a donut shape. The top surface and outer wall of each of the plurality of insulating ring patterns 162 may be surrounded by the oxide liner 164, and the oxide liner 164 may have a U-shaped vertical cross-section rotated by 90 degrees.

In some embodiments, the dielectric liner 149 may surround the top surface and bottom surface of the pad portion 130P and extend to the connection sidewall portion 160S2 of the cell contact plug 160. The dielectric liner 149 may extend to a relatively small distance from the cell contact hole 160H, and for example, the dielectric liner 149 may be exposed at the inner wall of the cell contact hole 160H. Thus, the dielectric liner 149 may surround the boundary between the upper sidewall portion 160S1 and the connection sidewall portion 160S2 of the cell contact plug 160. As illustrated in FIG. 6, the dielectric liner 149 may contact the sidewall (e.g., the upper sidewall portion 160S1) of the cell contact plug 160. Also, portions of the dielectric liner 149 that cover the top surface and bottom surface of the pad portion 130P may be arranged to vertically overlap the plurality of insulating ring patterns 162 and the oxide liner 164.

The dielectric liner 149 may extend to a relatively small distance from the cell contact hole 160H, and for example, as the dielectric liner 149 is exposed at the inner wall of the cell contact hole 160H, an etching process for removing a portion of the dielectric liner 149 exposed in the cell contact hole 160H may be precisely controlled.

As seen in FIG. 5, the bottom portion of the cell contact plug 160 may be surrounded by a first conductive landing via 90, and the first conductive landing via 90 may be covered by the interlayer insulating layer 80. The bottom surface of the first conductive landing via 90 may contact the top surface of the peripheral circuit line layer 74. The first conductive landing via 90 may include polysilicon doped with an n-type dopant.

Although not illustrated, a plurality of dummy channel structures (not illustrated) extending in the vertical direction Z from the top surface of the common source plate 110 through the plurality of gate electrodes 130 and the plurality of mold insulating layers 132 may be further formed in the connection area CON. The dummy channel structure may be formed to prevent the leaning or bending of the gate electrode 130 in the process of manufacturing the semiconductor device 100 and to secure the structural stability thereof. Each of the plurality of dummy channel structures may have a similar structure and shape to the plurality of channel structures 140.

A through hole 170H that passes through the insulating plug 120, the cover insulating layer 134, and the first upper insulating layer 136 may be arranged over the peripheral circuit connection area PRC, and a conductive through via 170 may be arranged in the through hole 170H. The conductive through via 170 may include, for example, tungsten, titanium, tantalum, copper, aluminum, titanium nitride, tantalum nitride, tungsten nitride, or any combination thereof.

A second conductive landing via 92 may surround the bottom sidewall of the conductive through via 170 and may be covered by the interlayer insulating layer 80. The bottom surface of the second conductive landing via 92 may contact the top surface of the peripheral circuit line layer 74. The second conductive landing via 92 may include polysilicon doped with an n-type dopant.

FIG. 5 illustrates that the second conductive landing via 92 may surround the sidewall of the conductive through via 170 and the bottom surface of the conductive through via 170 may contact the top surface of the peripheral circuit line layer 74. However, in some embodiments and unlike this, the bottom surface of the conductive through via 170 may contact the top surface of the second conductive landing via 92 and the bottom surface of the second conductive landing via 92 may contact the top surface of the peripheral circuit line layer 74.

The cell contact plug 160 may be connected to the peripheral circuit transistor 60TR through the first conductive landing via 90 and the peripheral circuit line layer 74, and the conductive through via 170 may be connected to the peripheral circuit transistor 60TR through the second conductive landing via 92 and the peripheral circuit line layer 74.

Over the memory cell area MCR, a bit line contact BLC may contact the conductive plug 148 of the channel structure 140 through the first upper insulating layer 136, and a bit line BL may be arranged over the bit line contact BLC. A second upper insulating layer 138 that covers the sidewall of the bit line BL may be arranged over the first upper insulating layer 136. Over the peripheral circuit connection area PRC, a wiring line ML1 may be arranged over the conductive through via 170.

Generally, in a structure including a cell contact plug landed on the top surface of the pad portion 130P, as the number of stacked gate electrodes 130 increases, a punch-through failure may occur because the pad portion 130P may be over-etched and connected to the gate electrode 130 under the pad portion 130P in a cell contact hole forming process. In order to solve this problem, a structure including the cell contact plug 160 passing through the gate electrode 130 has been proposed. However, there may be a problem in that the process of forming the cell contact plug 160 may not be precisely controlled, such as a portion of an oxide layer or the dielectric liner 149 remaining between the cell contact plug 160 and the gate electrode 130.

However, according to the above embodiments, as the distance between the cell contact hole 160H and the dielectric liner 149 is relatively small, the oxide layer may be prevented from remaining between the cell contact plug 160 and the gate electrode 130, and thus, the dielectric liner 149 between the cell contact plug 160 and the gate electrode 130 may be completely etched or almost completely etched. Accordingly, the process of forming the cell contact plug 160 may be precisely controlled or controlled more precisely. Also, the penetration of fluorine (F) or the like, which is included in an etchant material used in the process of etching the dielectric liner 149, toward the channel structure 140 may be significantly reduced or prevented.

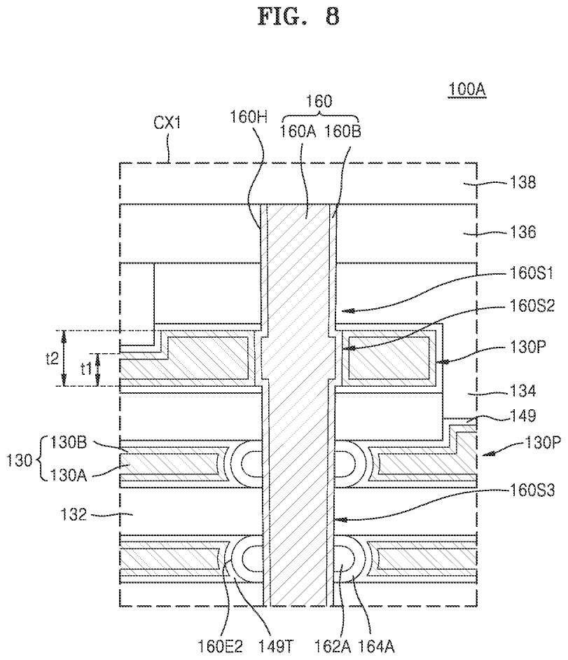

FIG. 8 is a cross-sectional view illustrating a semiconductor device 100A according to some embodiments. FIG. 8 is a cross-sectional view corresponding to an enlarged cross-sectional view of region CX1 of FIG. 5. In FIG. 8, like reference numerals as those in FIGS. 1 to 7 will denote like elements.

Referring to FIG. 8, a second extension portion 160E2 may be formed to have a greater width at a center portion thereof than at a top portion and a bottom portion thereof, an oxide liner 164A may be formed on and conform to the inner wall of the second extension portion 160E2, and a plurality of insulating ring patterns 162A may fill the second extension portion 160E2. Each of the plurality of insulating ring patterns 162A may have a rounded sidewall shape protruding outward.

A dielectric liner 149A may be arranged between the gate electrode 130 and the oxide liner 164A, and the dielectric liner 149A may have a sidewall portion that contacts the oxide liner 164A and is recessed inward. The sidewall portion may correspond to the sidewall shape of the oxide liner 164A that protrudes outward. Also, the dielectric liner 149A may have a tail portion 149T formed adjacent to the top portion and bottom portion of the second extension portion 160E2. The tail portion 149T may refer to a sidewall portion of each of the plurality of insulating ring patterns 162A protruding outward or a portion of the dielectric liner 149A vertically overlapping the oxide liner 164A.

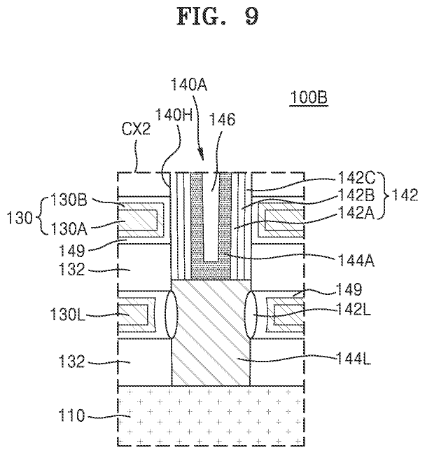

FIG. 9 is a cross-sectional view illustrating a semiconductor device 100B according to some embodiments. FIG. 9 is an enlarged view of a region corresponding to region CX2 of FIG. 5. In FIG. 9, like reference numerals as those in FIGS. 1 to 8 will denote like elements.

Referring to FIG. 9, a channel structure 140A may include a gate insulating layer 142, a channel layer 144A, a buried insulating layer 146, and a conductive plug 148 and may further include a contact semiconductor layer 144L and a bottom insulating layer 142L arranged at the bottom portion of the channel hole 140H. The channel layer 144A may not directly contact the common source plate 110, and the channel layer 144A may be electrically connected to the common source plate 110 through the contact semiconductor layer 144L. In some embodiments, the contact semiconductor layer 144L may include a silicon layer formed by a selective epitaxy growth (SEG) process by using the common source plate 110 arranged at the bottom portion of the channel hole 140H as a seed layer.

The bottom insulating layer 142L may be arranged between the lowermost gate electrode 130L and the contact semiconductor layer 144L. In some embodiments, the bottom insulating layer 142L may include silicon oxide and may be formed, for example, by performing an oxidation process on a portion of the sidewall of the contact semiconductor layer 144L.

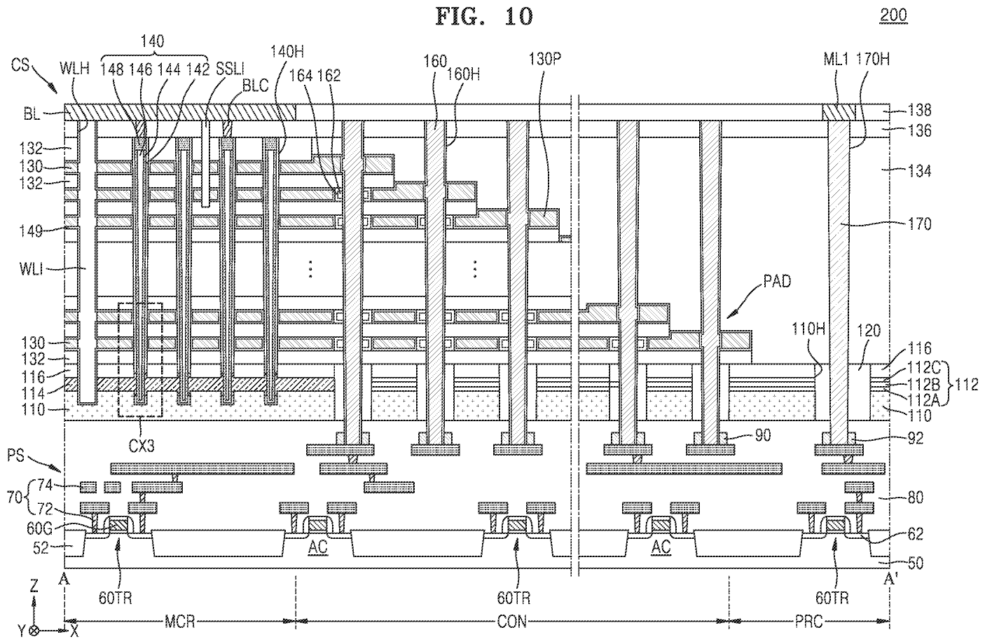

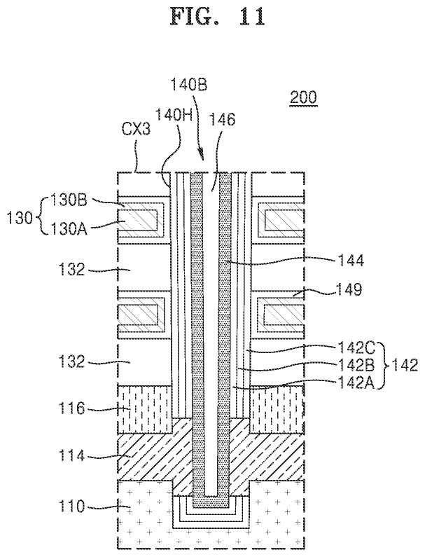

FIG. 10 is a cross-sectional view illustrating a semiconductor device 200 according to some embodiments. FIG. 11 is an enlarged view of region CX3 of FIG. 10. In FIGS. 10 and 11, like reference numerals as those in FIGS. 1 to 9 will denote like elements.

Referring to FIGS. 10 and 11, a horizontal semiconductor layer 114 and a support layer 116 may be sequentially stacked on the top surface of a common source plate 110 over a memory cell area MCR. A lower insulating layer 112 and the support layer 116 may be sequentially stacked on the top surface of a common source plate 110 over a connection area CON and a peripheral circuit connection area PRC.

In some embodiments, the lower insulating layer 112 may include a first insulating layer 112A, a second insulating layer 112B, and a third insulating layer 112C sequentially stacked on the common source plate 110. The first insulating layer 112A and the third insulating layer 112C may include silicon oxide, and the second insulating layer 112B may include silicon nitride.

In some embodiments, the horizontal semiconductor layer 114 may include doped polysilicon or undoped polysilicon. The horizontal semiconductor layer 114 may function as a portion of a common source area that connects the common source plate 110 and the channel layer 144 to each other. For example, the support layer 116 may include doped or undoped polysilicon. The support layer 116 may function as a support layer for preventing the collapse or fall of a mold stack in the process of removing a sacrificial material layer (not illustrated) for forming the horizontal semiconductor layer 114.

A channel structure 140B may include a gate insulating layer 142, a channel layer 144, a buried insulating layer 146, and a conductive plug 148. As illustrated in FIG. 11, the gate insulating layer 142 may be arranged on the inner wall and bottom portion of a channel hole 140H. The bottom surface of the channel layer 144 may be arranged on the gate insulating layer 142 and may not directly contact the common source plate 110, and the bottom sidewall of the channel layer 144 may be surrounded by the horizontal semiconductor layer 114.

A cell contact plug 160 may extend in the vertical direction Z through a first upper insulating layer 136, a cover insulating layer 134, a pad portion 130P, a plurality of gate electrodes 130, a plurality of mold insulating layers 132, an insulating plug 120, and a first conductive landing via 90. A plurality of insulating ring patterns 162 and an oxide liner 164 may be arranged between the cell contact plug 160 and the plurality of gate electrodes 130. A conductive through via 170 may extend in the vertical direction Z through the first upper insulating layer 136, the cover insulating layer 134, the insulating plug 120, and the second conductive landing via 92.

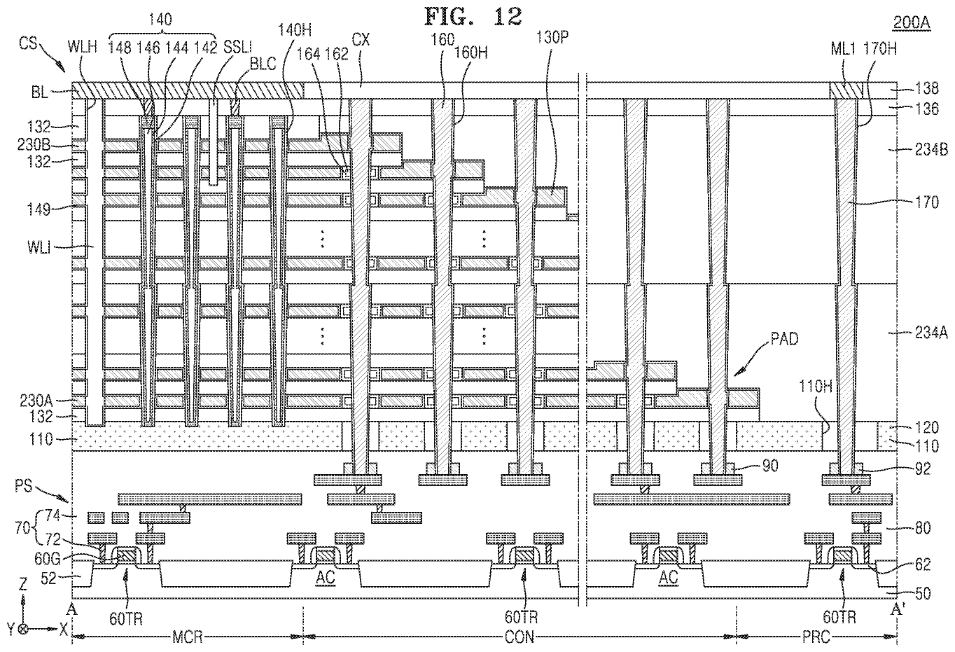

FIG. 12 is a cross-sectional view illustrating a semiconductor device 200A according to some embodiments.

Referring to FIG. 12, a first cover insulating layer 234A may be arranged to cover a plurality of first gate electrodes 230A and a pad structure PAD connected to the plurality of first gate electrodes 230A, and a second cover insulating layer 234B may be arranged on the plurality of first gate electrodes 230A and the first cover insulating layer 234A to cover a plurality of second gate electrodes 230B and a pad structure PAD connected to the plurality of second gate electrodes 230B.

A plurality of channel structures 140 may extend in the vertical direction Z through the plurality of first gate electrodes 230A and the plurality of second gate electrodes 230B. A cell contact plug 160 may extend in the vertical direction Z through the first cover insulating layer 234A and/or the second cover insulating layer 234B and the pad structure PAD, and a conductive through via 170 may extend in the vertical direction Z through the first cover insulating layer 234A and the second cover insulating layer 234B. A protrusion portion that protrudes outwardly may be formed on the sidewall of the cell contact plug 160 near the boundary between the first cover insulating layer 234A and the second cover insulating layer 234B; however, the inventive concepts and the present disclosure are not limited thereto.

Although FIG. 12 illustrates a structure in which a cell array structure CS is arranged over a peripheral circuit structure PS, the inventive concepts and the present disclosure are not limited thereto. In some embodiments, unlike the illustration in FIG. 12, the semiconductor device 200A may have a chip-to-chip (C2C) structure. As for the C2C structure, an upper chip including a cell array structure CSA may be fabricated on a first wafer, a lower chip including a peripheral circuit structure PS may be fabricated on a second wafer different from the first wafer, and then the upper chip and the lower chip may be connected to each other by a bonding method. For example, the bonding method may refer to a method of electrically connecting a bonding metal formed in the uppermost metal layer of the upper chip to a bonding metal formed in the uppermost metal layer of the lower chip. For example, when the bonding metal is formed of copper (Cu), the bonding method may be a Cu-to-Cu bonding method, and the bonding metal may also be formed of aluminum (Al) or tungsten (W). For example, the peripheral circuit structure PS may be arranged over the cell array structure CS, and the width of a plurality of gate electrodes 230A and 230B in the horizontal direction may increase as the distance from the peripheral circuit structure PS increases.

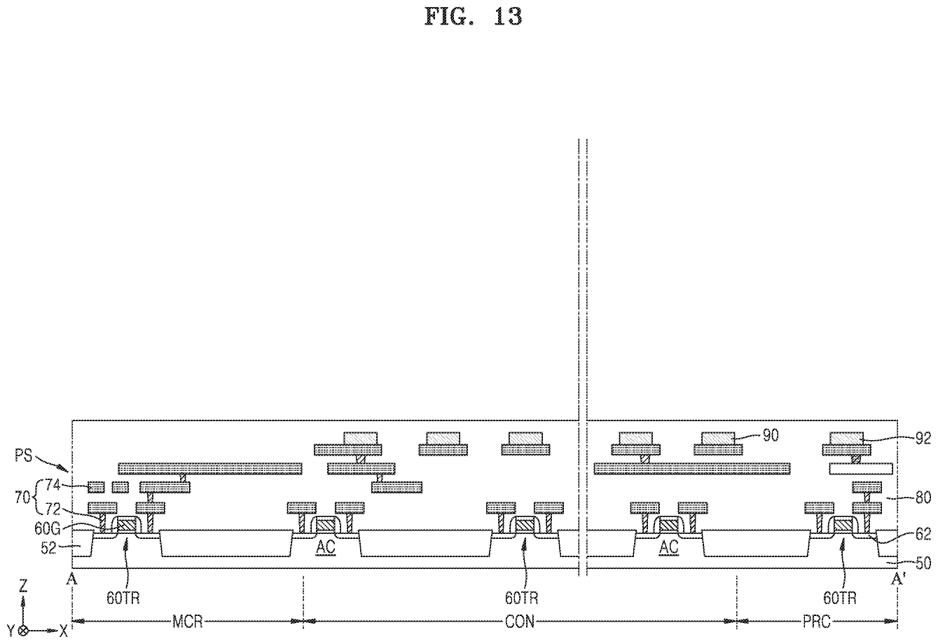

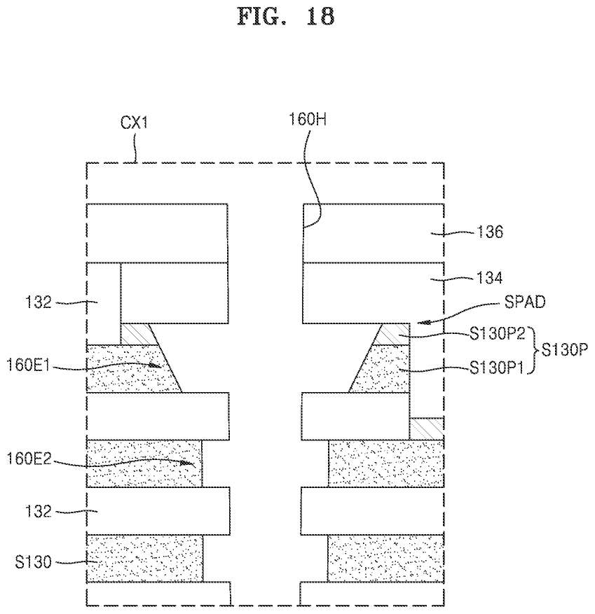

FIGS. 13 to 29 are cross-sectional views illustrating a method of manufacturing a semiconductor device 100 according to some embodiments. FIGS. 13 to 17, 24, and 27A are cross-sectional views corresponding to a cross-section taken along line A-A′ of FIG. 4, and FIGS. 18 to 23, 25, 26, 27B, 28, and 29 are cross-sectional views corresponding to a cross-section of region CX1 of FIG. 5.

Referring to FIG. 13, a peripheral circuit structure PS may be formed on a substrate 50. In some embodiments, the substrate 50 may be a monocrystalline silicon substrate. A plurality of peripheral circuit transistors 60TR may be formed on the substrate 50, and an interlayer insulating layer 80 and a peripheral circuit line structure 70 electrically connected to the peripheral circuit transistor 60TR may be formed.

First and second conductive landing vias 90 and 92 may be further formed on an uppermost peripheral circuit line layer 74 on a peripheral circuit connection area PRC. For example, the first and second conductive landing vias 90 and 92 may be formed by using polysilicon doped with an n-type dopant. The top surfaces of the first and second conductive landing vias 90 and 92 may be covered by the interlayer insulating layer 80.

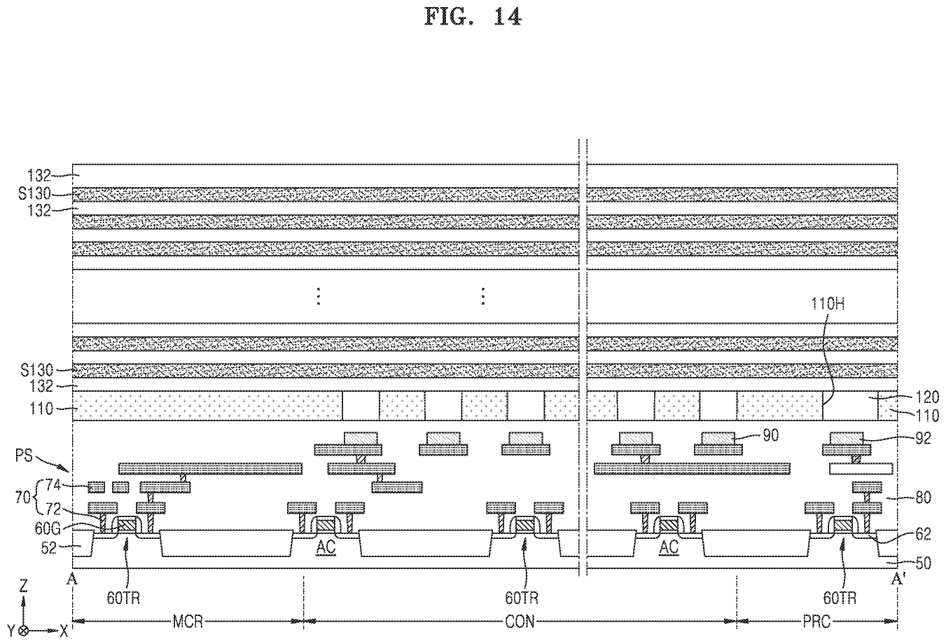

Referring to FIG. 14, a common source plate 110 may be formed on the interlayer insulating layer 80. In some embodiments, the common source plate 110 may be formed by using a semiconductor doped with an n-type dopant.

Thereafter, a mask pattern (not illustrated) may be formed on the common source plate 110, and an opening portion 110H may be formed by removing a portion of the common source plate 110 by using the mask pattern as an etch mask. The opening portion 110H may be formed in an area that vertically overlaps at least a portion of the peripheral circuit connection area PRC and the connection area CON.

Thereafter, an insulating layer (not illustrated) that fills the opening portion 110H may be formed on the common source plate 110, and an insulating plug 120 may be formed by planarizing the top portion of the insulating layer until the top surface of the common source plate 110 is exposed.

Thereafter, a plurality of mold insulating layers 132 and a plurality of sacrificial layers S130 may be alternately formed on the common source plate 110. In some embodiments, the plurality of mold insulating layers 132 may include an insulating material such as silicon oxide or silicon oxynitride, and the plurality of sacrificial layers S130 may include silicon nitride, silicon oxynitride, doped polysilicon, and/or the like.

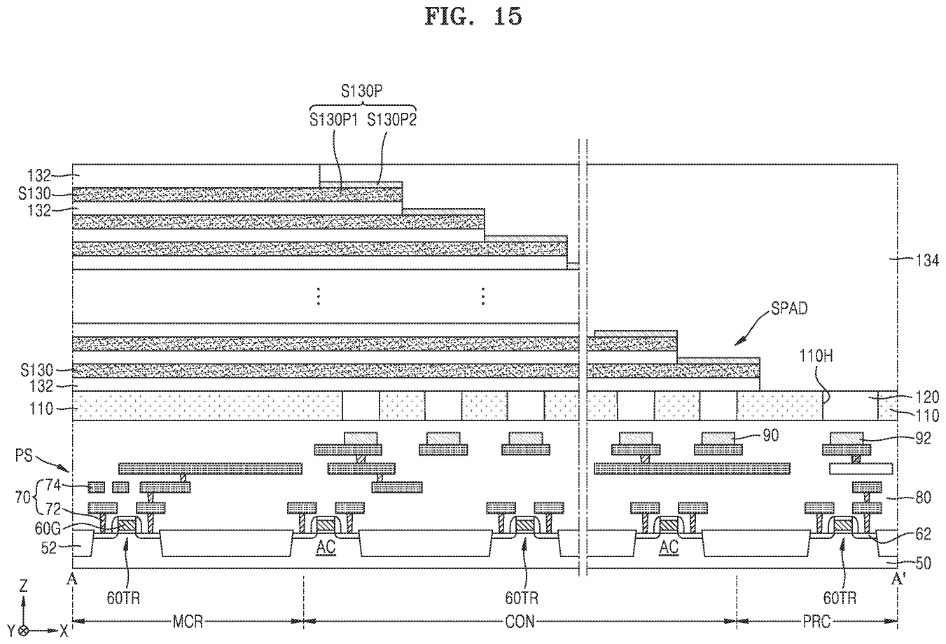

Referring to FIG. 15, a preliminary pad structure SPAD may be formed by sequentially patterning the plurality of mold insulating layers 132 and the plurality of sacrificial layers S130 on the connection area CON.

In some embodiments, the preliminary pad structure SPAD may be formed to have a stepped shape having an increasing length or a difference in the top surface level in the first horizontal direction (X direction) (see FIG. 4). For example, the preliminary pad structure SPAD may include a plurality of preliminary pad portions S130P, and each of the plurality of preliminary pad portions S130P may include a first preliminary pad layer S130P1 and a second preliminary pad layer S130P2.

In some embodiments, the first preliminary pad layer S130P1 may refer to the end portion of the plurality of sacrificial layers S130, and accordingly, the first preliminary pad layer S130P1 may include the same first insulating material as the plurality of sacrificial layers S130. The second preliminary pad layer S130P2 may include a material having an etch selectivity with respect to the first preliminary pad layer S130P1.

For example, the first preliminary pad layer S130P1 and the second preliminary pad layer S130P2 may include at least one of silicon nitride, silicon oxynitride, silicon oxide, silicon carbide, SiOC, a spin-on hardmask (SOH), and polysilicon; however, the inventive concepts and the present disclosure are not limited thereto. In some examples, the first preliminary pad layer S130P1 may include silicon nitride, and the second preliminary pad layer S130P2 may include silicon oxynitride.

Thereafter, a cover insulating layer 134 that covers the preliminary pad structure SPAD may be formed. The cover insulating layer 134 may include an insulating material such as silicon oxide or silicon oxynitride.

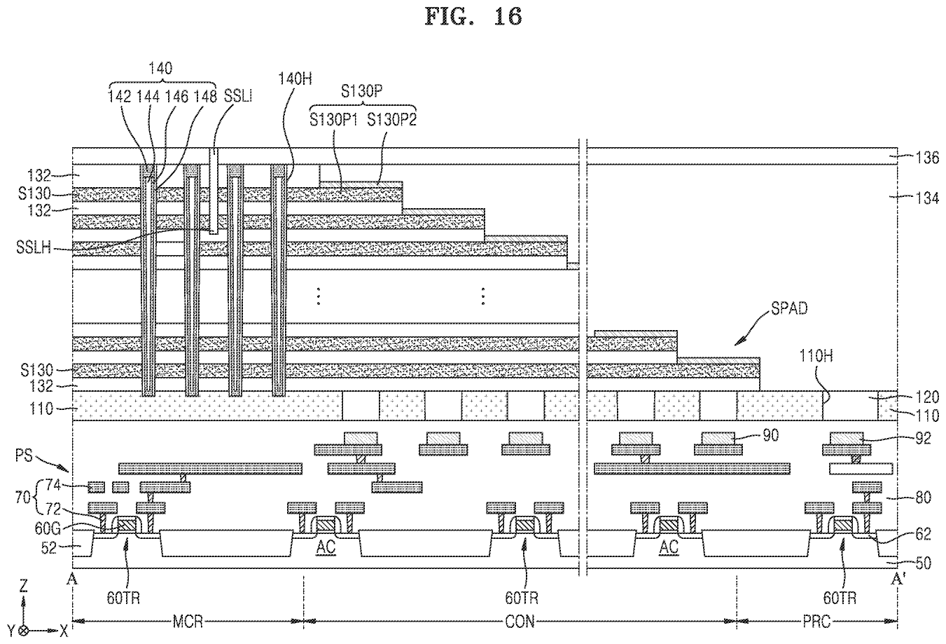

Referring to FIG. 16, a mask pattern (not illustrated) may be formed on the uppermost mold insulating layer 132 and the cover insulating layer 134, and a channel hole 140H may be formed by patterning the plurality of mold insulating layers 132 and the plurality of sacrificial layers S130 by using the mask pattern as an etch mask.

Thereafter, a channel structure 140 including a gate insulating layer 142, a channel layer 144, a buried insulating layer 146, and a conductive plug 148 may be formed on the inner wall of the channel hole 140H.

Although not illustrated, in the process of forming the channel structure 140, a dummy channel structure that passes through the preliminary pad structure SPAD may be simultaneously formed in the connection area CON.

Thereafter, a first upper insulating layer 136 may be formed that covers the uppermost mold insulating layer 132, the cover insulating layer 134, and the channel structure 140.

On the memory cell area MCR, a string separation opening portion SSLH may be formed by removing the first upper insulating layer 136, the two uppermost sacrificial layers S130, and the two uppermost mold insulating layers 132, and a string separation insulating layer SSLI that is within the string separation opening portion SSLH may be formed by using an insulating material.

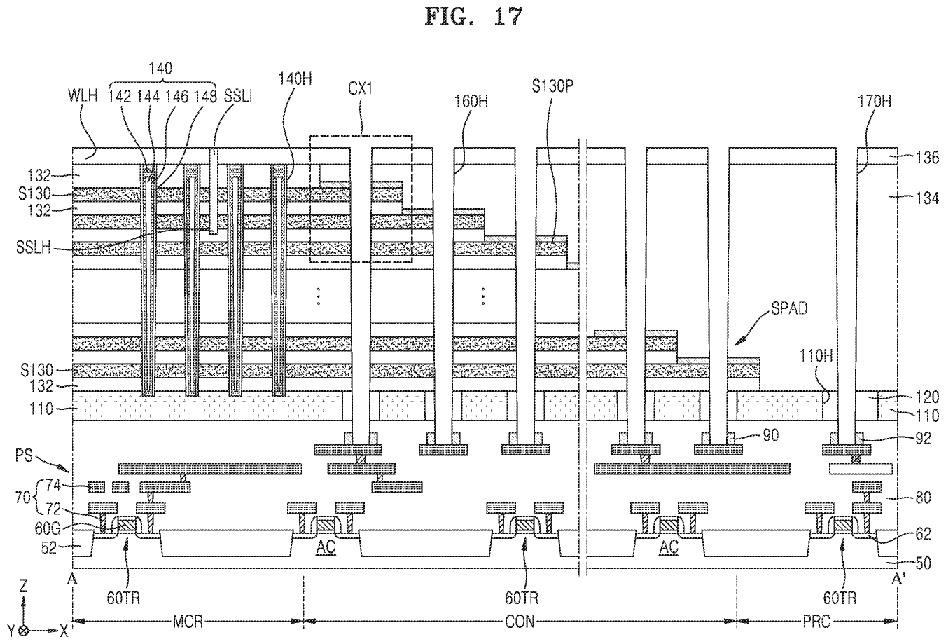

Referring to FIG. 17, on the connection area CON, a mask pattern (not illustrated) may be formed on the first upper insulating layer 136, and a cell contact hole 160H may be formed that passes through the first upper insulating layer 136, the preliminary pad structure SPAD, and the insulating plug 120, using the mask pattern as an etch mask. Also, by using the mask pattern as an etch mask, a through hole 170H that passes through the first upper insulating layer 136, the cover insulating layer 134, and the insulating plug 120 may be formed on the peripheral circuit connection area PRC.

In some embodiments, the cell contact hole 160H may pass through the preliminary pad portion 5130P and may extend in the vertical direction Z through the plurality of sacrificial layers S130 and the plurality of mold insulating layers 132 arranged at a lower vertical level than the preliminary pad portion S130P. The cell contact hole 160H may extend in the vertical direction Z from the top surface of the first upper insulating layer 136 to the bottom surface of the insulating plug 120 and may extend into the interlayer insulating layer 80 to expose the top surface of the first conductive landing via 90.

Referring to FIG. 18, a first extension portion 160E1 may be formed by removing a portion of the preliminary pad portion S130P exposed on the inner wall of the cell contact hole 160H, and a second extension portion 160E2 may be formed by removing a portion of the sacrificial layer S130 exposed on the inner wall of the cell contact hole 160H.

In some embodiments, the process of forming the first extension portion 160E1 and the second extension portion 160E2 may be an etching process using an etchant including a phosphoric acid (H₃PO₄). For example, the first extension portion 160E1 may be formed to have a greater width than the second extension portion 160E2.

In some embodiments, in the process of forming the first extension portion 160E1, the first preliminary pad layer S130P1 and the second preliminary pad layer S130P2 may have different etch rates, and accordingly, the first extension portion 160E1 may be formed to have an inclined sidewall. For example, in the etching process, the second preliminary pad layer S130P2 may be removed at a higher etch rate than the first preliminary pad layer S130P1, and in this case, the first extension portion 160E1 may have a shape with a positive slope such that an upper width thereof may be greater than a lower width thereof. However, the inventive concepts and the present disclosure are not limited thereto.

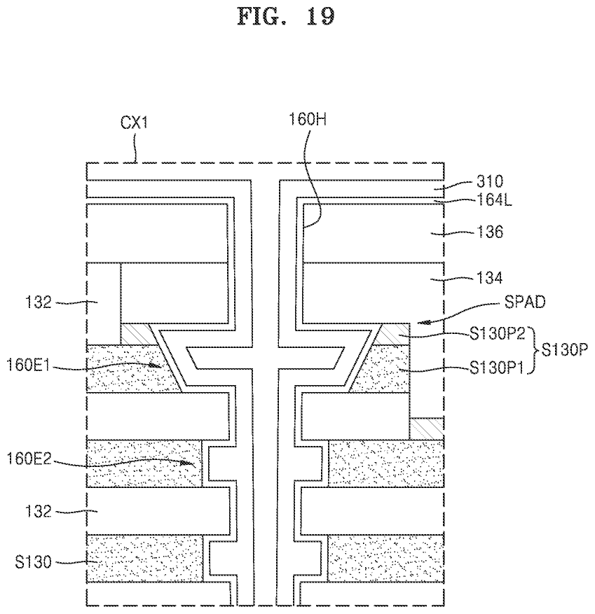

Referring to FIG. 19, an insulating liner 164L may be formed on the inner wall of the cell contact hole 160H. The insulating liner 164L may be formed on and conform to the inner wall of the first extension portion 160E1 and the second extension portion 160E2. In some embodiments, the insulating liner 164L may be formed by using silicon nitride.

Thereafter, a first insulating layer 310 may be formed on the inner wall of the cell contact hole 160H. The first insulating layer 310 may be formed on the insulating liner 164L to a thickness that completely fills the second extension portion 160E2 and does not fill the first extension portion 160E1. For example, the first insulating layer 310 may be formed by using silicon oxide.

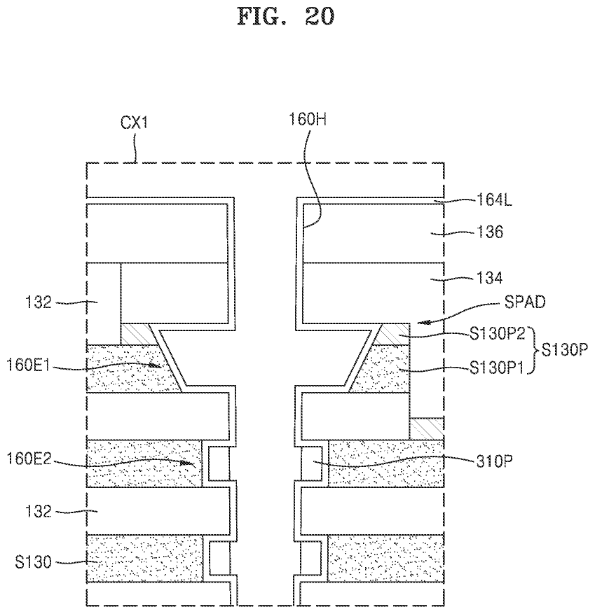

Referring to FIG. 20, a first insulating pattern 310P may be left in the second extension portion 160E2 by removing a portion of the first insulating layer 310 in the cell contact hole 160H by a wet etching process. In this case, all the portion of the first insulating layer 310 arranged on the inner wall of the first extension portion 160E1 may be removed, and the insulating liner 164L may be re-exposed in the first extension portion 160E1.

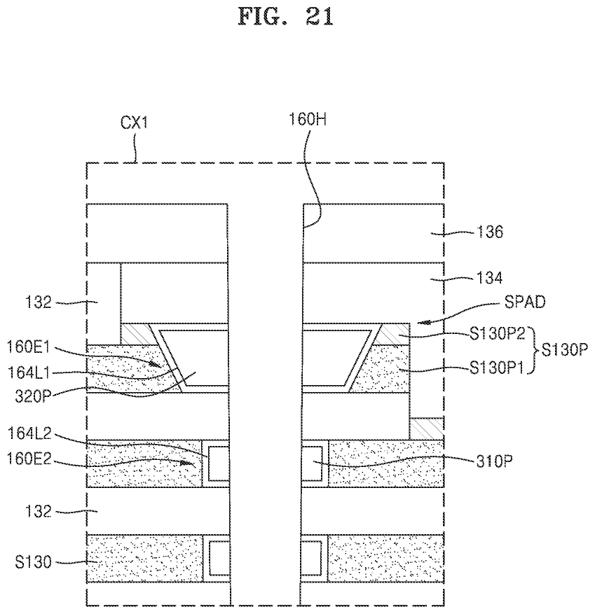

Referring to FIG. 21, a sacrificial ring pattern 320P within the first extension portion 160E1 of the cell contact hole 160H may be formed. In order to form the sacrificial ring pattern 320P, an insulating layer (not illustrated) may be formed on the inner wall of the cell contact hole 160H to a thickness that completely fills the first extension portion 160E1, and thereafter, the sacrificial ring pattern 320P may be left only in the first extension portion 160E1 by removing the insulating layer on the inner wall of the cell contact hole 160H. In some embodiments, the sacrificial ring pattern 320P may be formed by using a silicon nitride.

In the process of removing the insulating layer, a portion of the insulating liner 164L arranged on the inner wall of the cell contact hole 160H may be simultaneously removed. Here, the portion of the insulating liner 164L arranged on the inner wall of the first extension portion 160E1 will be referred to as a first insulation liner 164L1, and the portion of the insulation liner 164L arranged on the inner wall of the second extension portion 160E2 will be referred to as a second insulating liner 164L2.

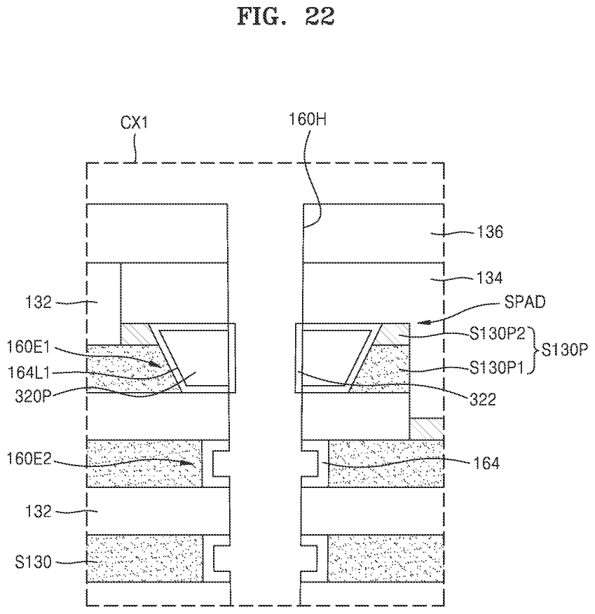

Referring to FIG. 22, the second insulating liner 164L2 may be exposed by removing the first insulating pattern 310P arranged in the second extension portion 160E2 on the inner wall of the cell contact hole 160H.

In some embodiments, the process of removing the first insulating pattern 310P may be a wet etching process. In the process of removing the first insulating pattern 310P, the sacrificial ring pattern 320P arranged in the first extension portion 160E1 may remain without being removed.

Thereafter, an oxidation process may be performed to form an oxide liner 164 from the second insulating liner 164L2 remaining in the second extension portion 160E2. In some embodiments, the oxidation process for forming the oxide liner 164 may include, but is not limited to, a thermal oxidation process, a dry oxidation process, a wet oxidation process, a plasma-assisted oxidation process, or the like.

In some embodiments, in the process for forming the oxide liner 164, a portion of the sacrificial ring pattern 320P in the first extension portion 160E1 may be oxidized to form an oxide layer 322.

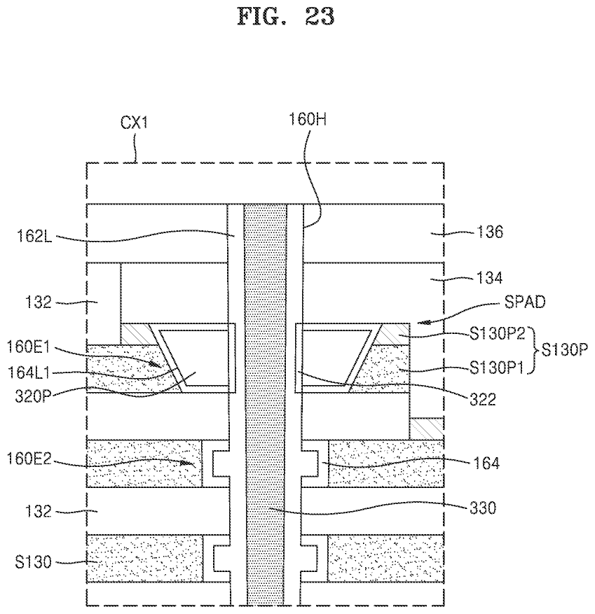

Referring to FIG. 23, a second insulating layer 162L may be formed in the cell contact hole 160H to a thickness that completely fills the second extension portion 160E2. In embodiments, the second insulating layer 162L may be formed by using silicon oxide.

Thereafter, a sacrificial plug 330 within the cell contact hole 160H may be formed on the second insulating layer 162L. For example, the sacrificial plug 330 may be formed by using polysilicon; however, the inventive concepts and the present disclosure are not limited thereto. Although not illustrated, an insulating spacer (not illustrated) may be further formed between the second insulating layer 162L and the sacrificial plug 330.

In embodiments, in the process for forming the sacrificial plug 330, a sacrificial through via 340 filling the through hole 170H may be simultaneously formed on the peripheral circuit connection area PRC. For example, the sacrificial through via 340 may be formed by using polysilicon; however, the inventive concepts and the present disclosure are not limited thereto.

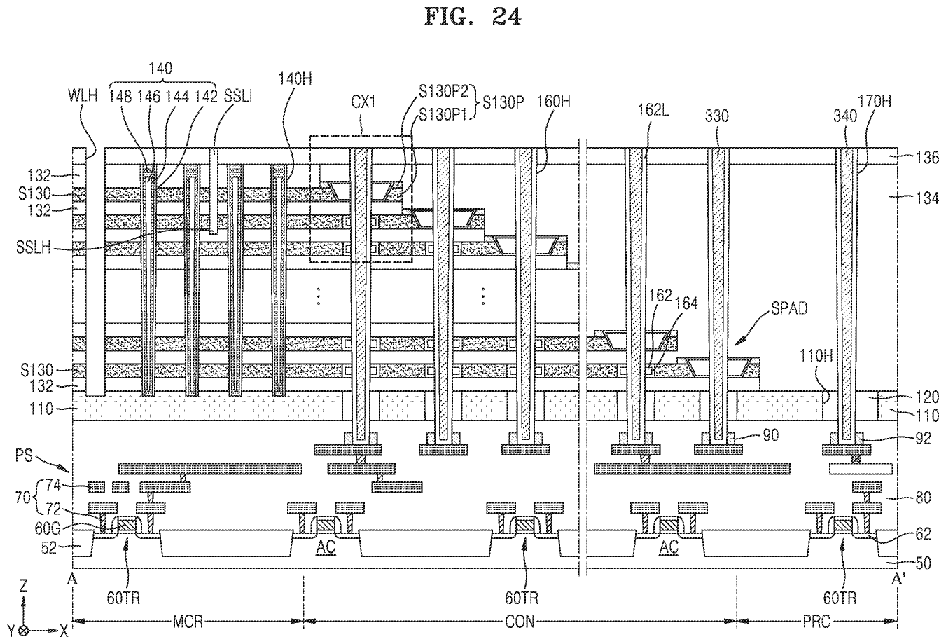

Referring to FIG. 24, a mask pattern (not illustrated) may be formed on the first upper insulating layer 136, and a gate stack separation opening portion WLH may be formed by removing a portion of the plurality of sacrificial layers S130 and the plurality of mold insulating layers 132 by using the mask pattern as an etch mask. The plurality of sacrificial layers S130 may be exposed on the inner wall of the gate stack separation opening portion WLH.

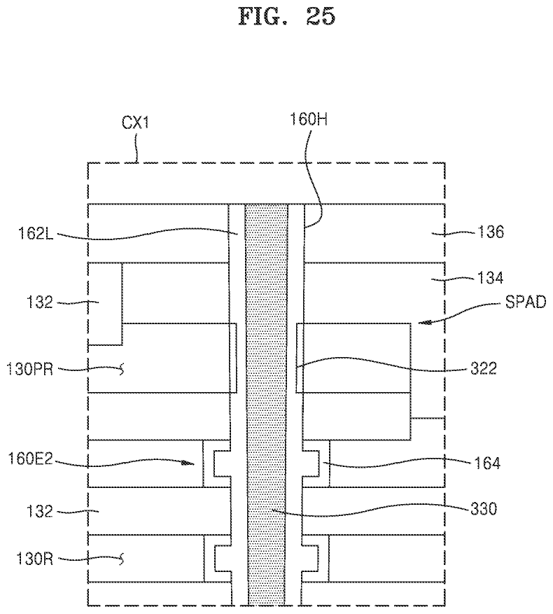

Referring to FIG. 25, the plurality of sacrificial layers S130 exposed at the sidewall of the gate stack separation opening portion WLH may be removed to form a plurality of gate spaces 130R. In some embodiments, the process of removing the plurality of sacrificial layers S130 may be a wet etching process using a phosphoric acid solution as an etchant. As the plurality of sacrificial layers S130 are removed, a portion of the sidewall of the channel structure 140 may be exposed.

In the process of removing the plurality of sacrificial layers S130, the preliminary pad portion 5130P, the first insulating liner 164L1, and the sacrificial ring pattern 320P may be simultaneously removed to form a pad portion space 130PR. Moreover, in the removing process, the oxide layer 322 may remain without being removed, and the oxide layer 322 may be exposed in the pad portion space 130PR.

Also, in the process of removing the plurality of sacrificial layers S130, the oxide liner 164 arranged at a lower vertical level than the pad portion space 130PR and arranged in the second extension portion 160E2 may remain without being removed, and accordingly, a sufficient separation distance between the sacrificial plug 330 and the plurality of gate spaces 130R may be secured.

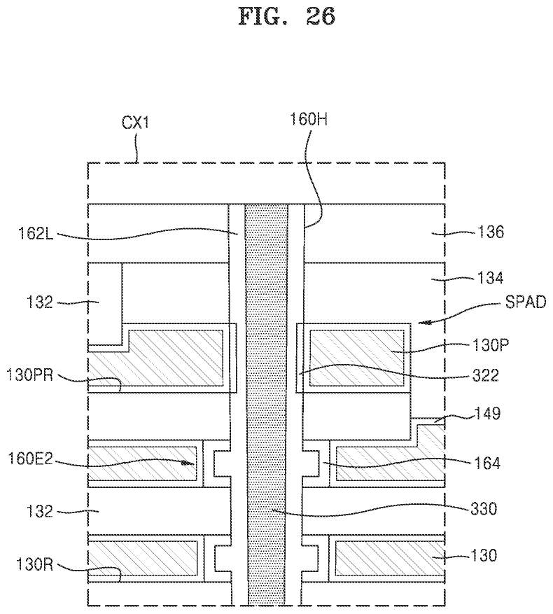

Referring to FIG. 26, a dielectric liner 149 may be formed on the inner wall of the pad portion space 130PR and the plurality of gate spaces 130R. The dielectric liner 149 may be arranged on and conform to the inner wall of the pad portion space 130PR and the plurality of gate spaces 130R, and may be arranged to surround the oxide layer 322 arranged in the pad portion space 130PR and to surround the oxide liner 164 arranged in the second extension portion 160E2.

Thereafter, a plurality of gate electrodes 130 may be formed by filling the plurality of gate spaces 130R with a conductive material. Also, a pad portion 130P may be formed by simultaneously filling the pad portion space 130PR with a conductive material.

In some embodiments, the dielectric liner 149, the oxide layer 322, and the second insulating layer 162L may be arranged between the pad portion 130P and the sacrificial plug 330, and the dielectric liner 149 may be arranged directly adjacent to the inner wall of the cell contact hole 160H (e.g., the inner wall of a vertically extending portion of the cell contact hole 160H). Thus, the distance between the pad portion 130P and the sacrificial plug 330 may be formed to be smaller than the distance between the gate electrode 130 and the sacrificial plug 330.

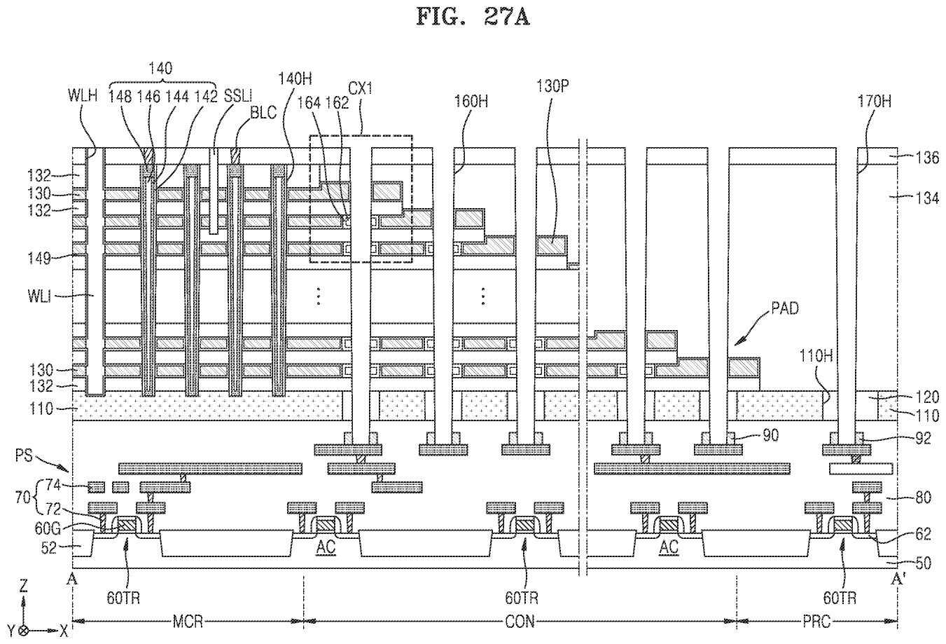

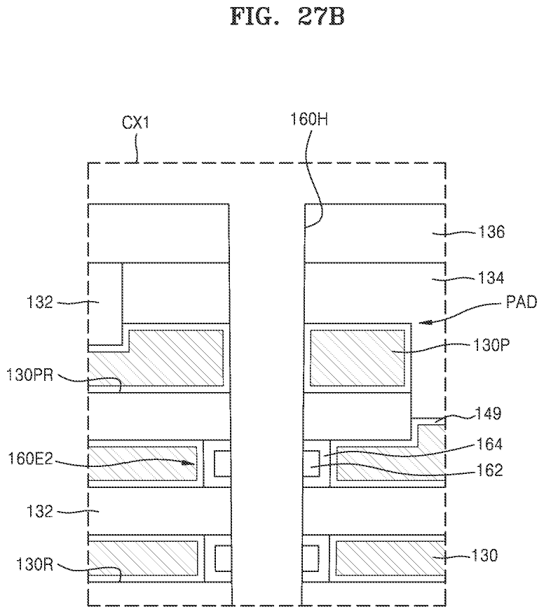

Referring to FIGS. 27A and 27B, a gate stack separation insulating layer WLI may be formed within the gate stack separation opening portion WLH using an insulating material.

Thereafter, the sacrificial plug 330 and the sacrificial through via 340 may be removed, and the inner walls of the cell contact hole 160H and the through hole 170H may be re-exposed.

As the sacrificial plug 330 and the sacrificial through via 340 are removed, the top surface of the first and second conductive landing vias 90 and 92 may be exposed at the bottom portion of the cell contact hole 160H and the through hole 170H respectively. Thereafter, an etch-back process may be performed on the bottom portion of the cell contact hole 160H and the through hole 170H to further extend the cell contact hole 160H and the through hole 170H in the vertical direction. The cell contact hole 160H and the through hole 170H may respectively pass through the first and second conductive landing vias 90 and 92, and the top surface of the uppermost peripheral circuit line layer 74 may be exposed at the bottom portion of the cell contact hole 160H and the through hole 170H.

In the removing process, a portion of the second insulating layer 162L arranged in the cell contact hole 160H may be removed, and an insulating ring pattern 162 may remain in the second extension portion 160E2. The inner wall of the insulating ring pattern 162 may be exposed in the cell contact hole 160H, and the top surface, bottom surface, and outer wall of the insulating ring pattern 162 may be covered by the oxide liner 164. The insulating ring pattern 162 may be formed to have an annular shape or a ring shape.

In the removing process, the oxide layer 322 arranged in the cell contact hole 160H may be simultaneously removed, and the sidewall of the dielectric liner 149 may be exposed in the cell contact hole 160H.

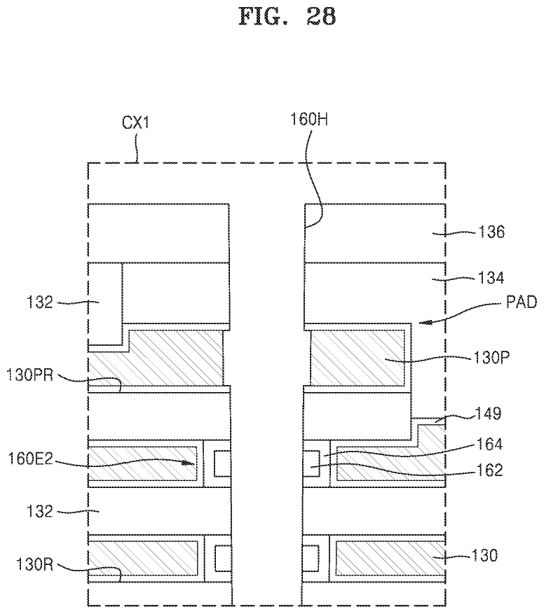

Referring to FIG. 28, the dielectric liner 149 exposed in the cell contact hole 160H may be removed, and the sidewall of the pad portion 130P may be exposed.

In some embodiments, an etching process using an etchant including fluorine (F) may be performed to remove the dielectric liner 149 including a high-k dielectric material. Because the sidewall of the dielectric liner 149 is arranged directly adjacent to the inner wall of the cell contact hole 160H, the process of etching the dielectric liner 149 may be precisely controlled or controlled more precisely.

In a method of manufacturing a semiconductor device according to a comparative example, when the dielectric liner 149 is arranged in an extension space extending in the horizontal direction (in the lateral direction) from the cell contact hole 160H (e.g., when the distance between the dielectric liner 149 and the cell contact hole 160H or the distance between the dielectric liner 149 and the sacrificial plug 330 is relatively great), an etching process for removing the dielectric liner 149 may need to be performed for a relatively long time. In this case, during the etching process, the etchant including fluorine (F) may easily penetrate toward the channel structure 140 through the interface between the mold insulating layer 132 and the gate electrode 130, and the electrical performance of the channel structure 140 may be degraded.

However, according to embodiments of the present inventive concepts, because the sidewall of the dielectric liner 149 is arranged directly adjacent to the inner wall of the cell contact hole 160H, the process of etching the dielectric liner 149 including a high-k dielectric material may be performed for a relatively short time, and the penetration of a material such as fluorine (F) toward the channel structure 140 may be significantly reduced or prevented.

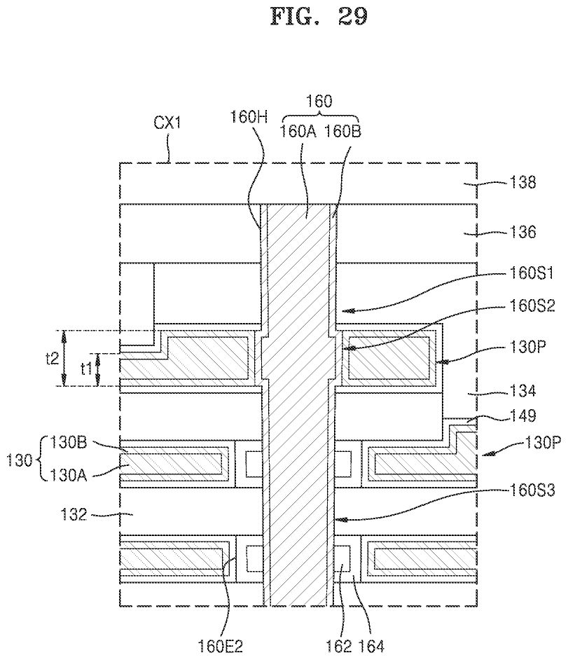

Referring to FIG. 29, a conductive layer (not illustrated) within the cell contact hole 160H and the through hole 170H (see FIG. 5) may be formed, and a cell contact plug 160 and a conductive through via 170 may be respectively formed in the cell contact hole 160H and the through hole 170H by planarizing the top portion of the conductive layer until the top surface of the first upper insulating layer 136 is exposed.

For example, the cell contact plug 160 and the conductive through via 170 may be formed by using tungsten, titanium, tantalum, copper, aluminum, titanium nitride, tantalum nitride, tungsten nitride, or any combination thereof.

Referring back to FIG. 5, a bit line contact BLC electrically connected to the channel structure 140 through the first upper insulating layer 136 may be formed.

Thereafter, a bit line BL electrically connected to the bit line contact BLC may be formed on the memory cell area MCR, and a wiring line ML1 electrically connected to the conductive through via 170 may be formed on the peripheral circuit connection area PRC. Thereafter, a second upper insulating layer 138 surrounding the sidewall of the bit line BL and the wiring line ML1 may be formed on the first upper insulating layer 136.

The semiconductor device 100 may be completed by performing the above processes.

Generally, in a structure including a cell contact plug landed on the top surface of the pad portion 130P, as the number of stacked gate electrodes 130 increases, a punch-through failure may occur because the pad portion 130P may be over-etched in the process of forming the cell contact hole 160H. In order to solve this problem, a structure including the cell contact plug 160 passing through the gate electrode 130 has been proposed. However, there may be a problem in that the process of forming the cell contact plug 160 may not be precisely controlled, such as a portion of an oxide layer or the dielectric liner 149 remaining between the cell contact plug 160 and the gate electrode 130. Also, in the process of removing the dielectric liner 149, a material such as fluorine (F) may penetrate into the channel structure 140 and thus the electrical performance of the channel structure 140 may be degraded.

However, according to the above embodiments of the present inventive concepts, as the distance between the cell contact hole 160H and the dielectric liner 149 is relatively small, the oxide layer may be prevented from remaining between the cell contact plug 160 and the gate electrode 130, and thus, the dielectric liner 149 between the cell contact plug 160 and the gate electrode 130 may be completely etched or etched more completely. Accordingly, the process of forming the cell contact plug 160 may be precisely controlled or controlled more precisely. Also, the penetration of a material such as fluorine (F) toward the channel structure 140 may be significantly reduced or prevented.

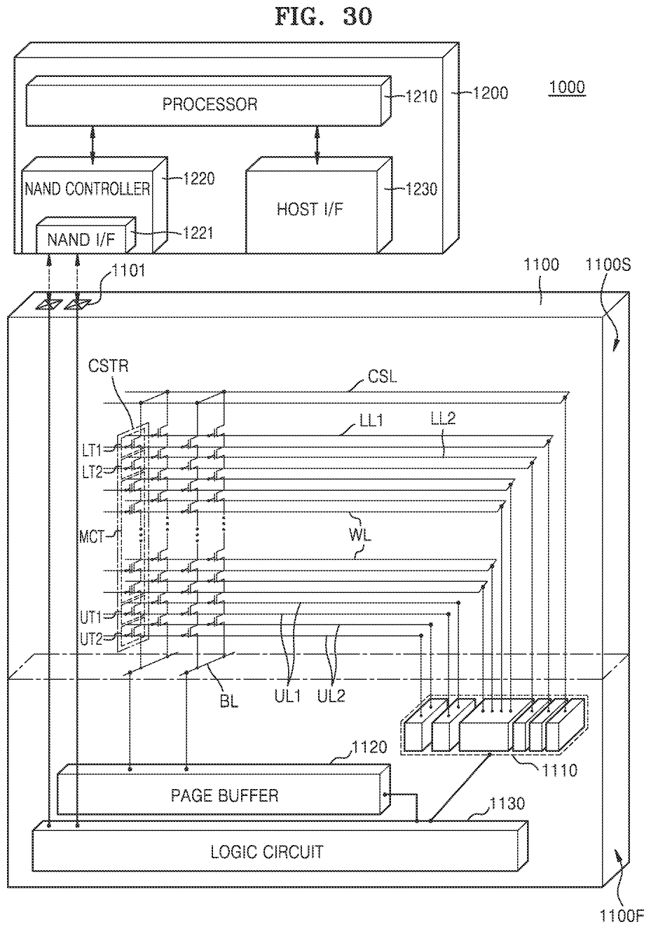

FIG. 30 is a diagram schematically illustrating a data storage system 1000 including a semiconductor device according to some embodiments.

Referring to FIG. 30, the data storage system 1000 may include one or more semiconductor devices 1100 and a memory controller 1200 electrically connected to the semiconductor device 1100. The data storage system 1000 may be, for example, a solid state drive (SSD) device, a universal serial bus (USB) device, a computing system, a medical device, or a communication device including at least one semiconductor device 1100.

The semiconductor device 1100 may be a nonvolatile semiconductor device, and for example, the semiconductor device 1100 may be a NAND flash semiconductor device including one of the semiconductor devices 10, 100, 100A, 100B, 200, and 200A described with reference to FIGS. 1 to 12. The semiconductor device 1100 may include a first structure 1100F and a second structure 1100S over the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, string selection transistors UT1 adjacent to the bit line BL, and a plurality of memory cell transistors MCT arranged between the ground selection transistors LT1 and LT2 and the string selection transistors UT1 and UT2. The number of ground selection transistors LT1 and LT2 and the number of string selection transistors UT1 and UT2 may be variously modified according to various embodiments.

In some embodiments, the ground selection lines LL1 and LL2 may be respectively connected to the gate electrodes of the ground selection transistors LT1 and LT2. The word line WL may be connected to the gate electrode of the memory cell transistor MCT. The string selection lines UL1 and UL2 may be respectively connected to the gate electrodes of the string selection transistors UT1 and UT2.

The common source line CSL, the ground selection lines LL1 and LL2, the word lines WL, and the string selection lines UL1 and UL2 may be connected to the row decoder 1110. The bit lines BL may be electrically connected to the page buffer 1120.

The semiconductor device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include a plurality of semiconductor devices 1100, and as such, the memory controller 1200 may control the plurality of semiconductor devices 1100.

The processor 1210 may control an overall operation of the data storage system 1000 including the memory controller 1200. The processor 1210 may operate according to certain firmware and may access the semiconductor device 1100 by controlling the NAND controller 1220. The NAND controller 1220 may include a NAND interface 1221 processing the communication with the semiconductor device 1100. A control command configured to control the semiconductor device 1100, data to be written into the memory cell transistors MCT of the semiconductor device 1100, data to be read from the memory cell transistors MCT of the semiconductor device 1100, and/or the like may be transmitted through the NAND interface 1221. The host interface 1230 may provide a communication function between the data storage system 1000 and an external host. When receiving a control command from the external host through the host interface 1230, the processor 1210 may control the semiconductor device 1100 in response to the control command.

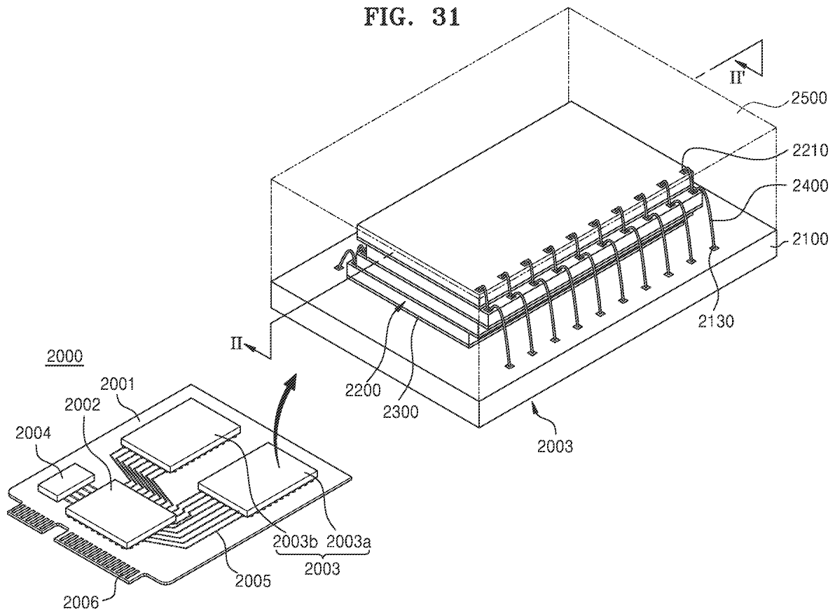

FIG. 31 is a perspective view schematically illustrating a data storage system 2000 including a semiconductor device according to some embodiments.

Referring to FIG. 31, the data storage system 2000 according to some embodiments may include a main board 2001 and a memory controller 2002, one or more semiconductor packages 2003, and a DRAM 2004 mounted on the main board 2001. The semiconductor package 2003 and the DRAM 2004 may be connected to the memory controller 2002 by a plurality of line patterns 2005 formed over the main board 2001.

The main board 2001 may include a connector 2006 including a plurality of pins coupled to an external host. The number and arrangement of the plurality of pins in the connector 2006 may vary according to the communication interface between the data storage system 2000 and the external host. In some embodiments, the data storage system 2000 may communicate with the external host according to any one of various interfaces, such as Universal Serial Bus (USB), Peripheral Component Interconnect Express (PCI-Express), Serial Advanced Technology Attachment (SATA), and Universal Flash Storage (UFS) M-Phy, as examples. In some embodiments, the data storage system 2000 may operate by the power supplied from the external host through the connector 2006. The data storage system 2000 may further include a power management integrated circuit (PMIC) that distributes the power supplied from the external host to the memory controller 2002 and the semiconductor package 2003.

The memory controller 2002 may write/read data to/from the semiconductor package 2003 and may improve the operating speed of the data storage system 2000.

The DRAM 2004 may be a buffer memory for reducing the speed difference between the external host and the semiconductor package 2003 that is a data storage space. The DRAM 2004 included in the data storage system 2000 may operate as a type of cache memory and may provide a space for temporarily storing data in a control operation for the semiconductor package 2003. When the DRAM 2004 is included in the data storage system 2000, the memory controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 over the package substrate 2100, an adhesive layer 2300 arranged on the bottom surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 over the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 30. Each of the plurality of semiconductor chips 2200 may include at least one of the semiconductor devices 10, 100, 100A, 100B, 200, and 200A described with reference to FIGS. 1 to 12.

In some embodiments, the connection structure 2400 may be a bonding wire electrically connecting the input/output pad 2210 to the package upper pad 2130. Thus, in the first and second semiconductor packages 2003a and 2003b, the plurality of semiconductor chips 2200 may be electrically connected to each other by a bonding wire method and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including a through silicon via (TSV), instead of by the bonding wire type connection structure 2400.

In some embodiments, the memory controller 2002 and the plurality of semiconductor chips 2200 may be included in one package. In some embodiments, the memory controller 2002 and the plurality of semiconductor chips 2200 may be mounted on a separate interposer substrate that is different from the main board 2001, and the memory controller 2002 and the plurality of semiconductor chips 2200 may be connected to each other.

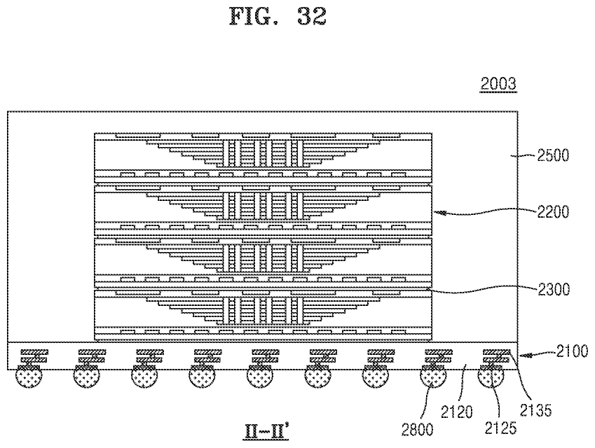

FIG. 32 is a cross-sectional view schematically illustrating semiconductor packages 2003 according to some embodiments. FIG. 32 is a cross-sectional view taken along line of FIG. 31.

Referring to FIG. 32, in the semiconductor package 2003, the package substrate 2100 may be a printed circuit board. The package substrate 2100 may include a package substrate body 2120, a plurality of package upper pads 2130 (see FIG. 31) arranged on the top surface of the package substrate body 2120, a plurality of lower pads 2125 arranged on the bottom surface of the package substrate body 2120 or exposed through the bottom surface thereof, and a plurality of internal lines 2135 electrically connecting the plurality of package upper pads 2130 (see FIG. 31) to the plurality of lower pads 2125 in the package substrate body 2120. As illustrated in FIG. 31, the plurality of package upper pads 2130 may be electrically connected to the plurality of connection structures 2400. As illustrated in FIG. 32, the plurality of lower pads 2125 may be connected through a plurality of conductive bumps 2800 to the plurality of line patterns 2005 over the main board 2001 of the data storage system 2000 illustrated in FIG. 31. Each of the plurality of semiconductor chips 2200 may include at least one of the semiconductor devices 10, 100, 100A, 100B, 200, and 200A described with reference to FIGS. 1 to 12.

While the inventive concepts have been particularly shown and described with reference to some example embodiments thereof, it will be understood that various changes in form and details may be made therein without departing from the scope of the following claims.

What is claimed is:

1. A method of manufacturing a semiconductor device, the method comprising:
forming a mold stack including a plurality of insulating layers and a plurality of sacrificial layers alternately arranged on a substrate;
forming a preliminary pad structure by sequentially patterning the mold stack, wherein the preliminary pad structure includes a preliminary pad portion connected to at least one sacrificial layer among the plurality of sacrificial layers, and the preliminary pad portion has a greater thickness than the at least one sacrificial layer in a vertical direction that is perpendicular to an upper surface of the substrate;
forming a cell contact hole that extends in the vertical direction through the preliminary pad portion and through a plurality of sacrificial layer portions under the preliminary pad portion;
forming a first extension portion and a plurality of second extension portions by laterally expanding the preliminary pad portion and the plurality of sacrificial layer portions exposed at an inner wall of the cell contact hole;
forming a first insulating liner and a sacrificial ring pattern in the first extension portion;
forming an oxide liner and an insulating ring pattern in each of the plurality of second extension portions;
forming a sacrificial plug within the cell contact hole; and
replacing the plurality of sacrificial layers with a plurality of gate electrodes and replacing the preliminary pad portion, the first insulating liner, and the sacrificial ring pattern with a pad portion.

2. The method of claim 1, wherein the forming of the oxide liner and the insulating ring pattern includes:
forming a second insulating liner on inner walls of the plurality of second extension portions;
forming an oxide liner on the inner walls of the plurality of second extension portions by performing an oxidation process on the second insulating liner; and
forming an insulating ring pattern within the plurality of second extension portions on the inner walls of the plurality of second extension portions and on the oxide liner.

3. The method of claim 2, wherein the first insulating liner and the second insulating liner are formed in a single process.

4. The method of claim 1, wherein the oxide liner surrounds a top surface, a bottom surface, and an outer wall of the insulating ring pattern, and
wherein the oxide liner is arranged between the insulating ring pattern and one of the gate electrodes corresponding thereto.

5. The method of claim 1, wherein, when viewed in a plan view, the sacrificial plug is surrounded by the oxide liner and the insulating ring pattern.

6. The method of claim 1, wherein the replacing of the plurality of sacrificial layers with the plurality of gate electrodes and the replacing of the preliminary pad portion, the first insulating liner, and the sacrificial ring pattern with the pad portion comprise:
forming a plurality of gate spaces by removing the plurality of sacrificial layers;
forming a pad space in communication with each of the plurality of gate spaces, by removing the preliminary pad portion, the first insulating liner, and the sacrificial ring pattern;
forming a dielectric liner on inner walls of the plurality of gate spaces and the pad space; and
forming, on the dielectric liner, the plurality of gate electrodes within the plurality of gate spaces and forming the pad portion within the pad space.

7. The method of claim 6, further comprising:
removing the sacrificial plug and exposing the cell contact hole;
removing a portion of the dielectric liner exposed in the cell contact hole and exposing a sidewall of the pad portion; and
forming, in the cell contact hole, a cell contact plug contacting the sidewall of the pad portion, the oxide liner, and the insulating ring pattern and extending in the vertical direction.

8. The method of claim 7, wherein the dielectric liner includes a high-k dielectric oxide comprising hafnium oxide, aluminum oxide, zirconium oxide, tantalum oxide, or a combination thereof.

9. The method of claim 8, wherein the dielectric liner is arranged on top surfaces and bottom surfaces of the plurality of gate electrodes and on a top surface and a bottom surface of the pad portion, and wherein the dielectric liner is absent from between the pad portion and the cell contact plug.

10. The method of claim 1, wherein the preliminary pad portion includes:
a first preliminary pad layer that includes a first insulating material that is the same as a material included in the plurality of sacrificial layers; and
a second preliminary pad layer located on the first preliminary pad layer and including a second insulating material that is different from the material included in the plurality of sacrificial layers.

11. The method of claim 10, wherein the first extension portion has an inclined sidewall, and
wherein a top portion of the first extension portion has a greater width than a bottom portion of the first extension portion.

12. A method of manufacturing a semiconductor device, the method comprising:
forming a mold stack including a plurality of insulating layers and a plurality of sacrificial layers alternately arranged on a substrate;
forming a preliminary pad structure by sequentially patterning the mold stack, wherein the preliminary pad structure has a stepped shape and includes a preliminary pad portion connected to at least one sacrificial layer among the plurality of sacrificial layers, and the preliminary pad portion has a greater thickness than the at least one sacrificial layer in a vertical direction that is perpendicular to an upper surface of the substrate;
forming a cell contact hole, which extends in the vertical direction through the preliminary pad portion and a plurality of sacrificial layer portions under the preliminary pad portion and includes a first extension portion extending in a horizontal direction;
forming a sacrificial ring pattern in the first extension portion;
forming a sacrificial plug within the cell contact hole;
forming a plurality of gate spaces by removing the plurality of sacrificial layers and forming a pad space by removing the preliminary pad portion and the sacrificial ring pattern;
forming a dielectric liner on inner walls of the plurality of gate spaces and the pad space;
forming a plurality of gate electrodes within the plurality of gate spaces on the dielectric liner and forming a pad portion within the pad space;
removing the sacrificial plug to expose a sidewall of the pad portion and removing a portion of the dielectric liner exposed in the cell contact hole; and
forming, in the cell contact hole, a cell contact plug contacting the sidewall of the pad portion and extending in the vertical direction.

13. The method of claim 12, wherein the forming of the cell contact hole includes:
forming the cell contact hole, which extends in the vertical direction, through the preliminary pad portion and a plurality of sacrificial layer portions under the preliminary pad portion; and
forming the first extension portion by removing a portion of the preliminary pad portion exposed at an inner wall of the cell contact hole and forming a plurality of second extension portions by removing the plurality of sacrificial layer portions exposed at an inner wall of the cell contact hole.

14. The method of claim 13, further comprising, prior to the forming of the sacrificial ring pattern:
forming a first insulating liner on an inner wall of the first extension portion and forming a second insulating liner on inner walls of the plurality of second extension portions; and
forming an oxide liner on the inner walls of the plurality of second extension portions by performing an oxidation process on the second insulating liner.

15. The method of claim 14, further comprising forming an insulating ring pattern on the inner walls of the plurality of second extension portions and on the oxide liner within the plurality of second extension portions.

16. The method of claim 12, wherein the preliminary pad portion includes:
a first preliminary pad layer that includes a first insulating material that is the same as a material included in the plurality of sacrificial layers; and
a second preliminary pad layer that is located on the first preliminary pad layer and that includes a second insulating material that is different from the material included in the plurality of sacrificial layers.

17. The method of claim 16, wherein the first extension portion has an inclined sidewall, and
wherein a top portion of the first extension portion has a greater width than a bottom portion of the first extension portion.

18. A method of manufacturing a semiconductor device, the method comprising:
forming a mold stack that includes a plurality of insulating layers and a plurality of sacrificial layers alternately arranged on a substrate;
forming a preliminary pad structure by sequentially patterning the mold stack, wherein the preliminary pad structure includes a preliminary pad portion connected to at least one sacrificial layer among the plurality of sacrificial layers;
forming a cell contact hole, which extends in a vertical direction perpendicular to an upper surface of the substrate, through the preliminary pad portion and a plurality of sacrificial layer portions under the preliminary pad portion;
forming a first extension portion and a plurality of second extension portions by laterally expanding the preliminary pad portion and the plurality of sacrificial layer portions exposed at an inner wall of the cell contact hole;
forming an insulating liner on an inner wall of the cell contact hole, on an inner wall of the first extension portion, and on inner walls of the plurality of second extension portions;
forming a sacrificial ring pattern within the first extension portion on the inner wall of the first extension portion;
converting a portion of the insulating liner arranged on the inner walls of the plurality of second extension portions into an oxide liner by performing an oxidation process;
forming a plurality of insulating ring patterns respectively within the plurality of second extension portions on the inner walls of the plurality of second extension portions;
forming a sacrificial plug within the cell contact hole; and
replacing the plurality of sacrificial layers with a plurality of gate electrodes and replacing the preliminary pad portion, the insulating liner, and the sacrificial ring pattern with a pad portion.

19. The method of claim 18, wherein the replacing of the plurality of sacrificial layers with the plurality of gate electrodes and the replacing of the preliminary pad portion, the insulating liner, and the sacrificial ring pattern with the pad portion include:
forming a plurality of gate spaces by removing the plurality of sacrificial layers;
forming a pad space in communication with each of the plurality of gate spaces by removing the preliminary pad portion, the insulating liner, and the sacrificial ring pattern;
forming a dielectric liner on inner walls of the plurality of gate spaces and the pad space; and
forming, on the dielectric liner, the plurality of gate electrodes filling the plurality of gate spaces and forming the pad portion within the pad space.

20. The method of claim 19, further comprising: removing the sacrificial plug and exposing the cell contact hole;
removing a portion of the dielectric liner exposed in the cell contact hole and exposing a sidewall of the pad portion; and
forming, in the cell contact hole, a cell contact plug contacting the sidewall of the pad portion, the oxide liner, and the plurality of insulating ring patterns and extending in the vertical direction.
